(19) United States
(12) Patent Application Publication
(10) Pub. No.: US 2025/0014799 A1
(43) Pub. Date: Jan. 9, 2025

(54) INSULATING CHIP AND SIGNAL TRANSMISSION DEVICE

(71) Applicant: ROHM CO., LTD., Kyoto (JP)

(72) Inventor: Bungo TANAKA, Kyoto-shi (JP)

(73) Assignee: ROHM CO., LTD., Kyoto (JP)

(21) Appl. No.: 18/884,662

(22) Filed: Sep. 13, 2024

Related U.S. Application Data
(63) Continuation of application No. PCT/JP2023/008970, filed on Mar. 9, 2023.

(30) Foreign Application Priority Data
Mar. 17, 2022 (JP) 2022-042493

(51) Int. Cl. H01F 17/00; H01F 27/32; H01F 38/14; H01L 23/64

(52) U.S. Cl. CPC H01F 17/0013; H01F 38/14; H01L 23/645; H01F 2017/0086; H01F 2027/329; H01F 2038/143

(57) ABSTRACT

An insulating chip includes: a first unit; and a second unit disposed on the first unit, wherein the first unit includes a first element insulation layer including a first element back surface and a first element head surface, a first insulation element embedded in the first element insulation layer, and a first connection electrode exposed from the first element back surface, the second unit includes a second element insulation layer including a second element back surface and a second element head surface, a second insulation element opposed to the first insulation element, and a second connection electrode exposed from the second element back surface, the first unit and the second unit are disposed so that the first element back surface is in contact with the second element back surface and the first connection electrode is electrically connected to the second connection electrode.

### CROSS-REFERENCE TO RELATED APPLICATIONS

This application is a continuation of, and claims the benefit of priority from International Application No. PCT/JP2023/008970, filed on Mar. 9, 2023, which claims the benefit of priority from Japanese Patent Application No. 2022-042493, filed on Mar. 17, 2022, the entire contents of each of which are incorporated herein by reference.

### BACKGROUND

The present disclosure relates to an insulating chip and a signal transmission device.

A known example of a signal transmission device is an insulated gate driver that applies a gate voltage to the gate of a switching element such as a transistor. In an example, the gate driver uses an insulating chip having a structure in which a first coil and a second coil are disposed in an element insulation layer and opposed to each other in a thickness-wise direction of the element insulation layer (refer to, for example, Japanese Laid-Open Patent Publication No. 2018-78169).

### BRIEF DESCRIPTION OF DRAWINGS

FIG. 1 is a schematic circuit diagram showing the circuit configuration of a first embodiment of a signal transmission device.

FIG. 2 is a schematic cross-sectional view showing the signal transmission device of the first embodiment.

FIG. 3 is a schematic cross-sectional view showing an insulating chip in the signal transmission device shown in FIG. 2.

FIG. 4 is a schematic cross-sectional view of the insulating chip shown in FIG. 3 when a first unit and a second unit are separated from each other.

FIG. 5 is a schematic cross-sectional view showing a second embodiment of an insulating chip.

FIG. 6 is a schematic circuit diagram showing the circuit configuration of a third embodiment of a signal transmission device.

FIG. 7 is a schematic cross-sectional view showing an insulating chip in the signal transmission device of the third embodiment.

FIG. 8 is a schematic circuit diagram showing the circuit configuration of a fourth embodiment of a signal transmission device.

FIG. 9 is a schematic cross-sectional view showing the signal transmission device of the fourth embodiment.

FIG. 10 is a schematic cross-sectional view showing an insulating chip in the signal transmission device shown in FIG. 9.

FIG. 11 is a schematic cross-sectional view showing a modified example of an insulating chip.

FIG. 12 is a schematic cross-sectional view showing a modified example of an insulating chip.

FIG. 13 is a schematic cross-sectional view showing a modified example of an insulating chip.

FIG. 14 is a schematic cross-sectional view showing a modified example of an insulating chip.

FIG. 15 is a schematic cross-sectional view showing a modified example of an insulating chip.

FIG. 16 is a schematic cross-sectional view showing a modified example of an insulating chip.

FIG. 17 is a schematic cross-sectional view showing a modified example of an insulating chip.

FIG. 18 is a schematic cross-sectional view showing a modified example of an insulating chip.

FIG. 19 is a schematic cross-sectional view showing a modified example of an insulating chip.

FIG. 20 is a schematic cross-sectional view showing a modified example of an insulating chip.

FIG. 21 is a schematic cross-sectional view showing a modified example of an insulating chip.

FIG. 22 is a schematic circuit diagram showing the circuit configuration of a signal transmission device of a modified example.

FIG. 23 is a schematic cross-sectional view of the signal transmission device shown in FIG. 22.

FIG. 24 is a schematic cross-sectional view showing a modified example of a signal transmission device.

### DETAILED DESCRIPTION

Embodiments of an insulating chip and a signal transmission device according to the present disclosure will be described below with reference to the drawings.

In the drawings, components may not be drawn to scale for simplicity and clarity of illustration. In a cross-sectional view, hatching may be omitted to facilitate understanding. The accompanying drawings illustrate exemplary embodiments in accordance with the present disclosure and are not intended to limit the present disclosure.

The following detailed description includes exemplary embodiments of a device, a system, and a method according to the present disclosure. The detailed description is illustrative and is not intended to limit embodiments of the present disclosure or the application and use of the embodiments.

### First Embodiment

### Structure of Signal Transmission Device

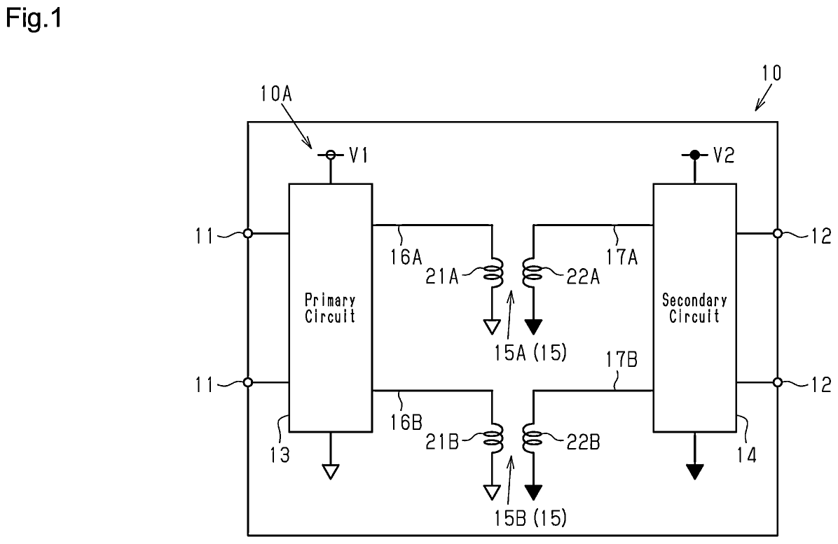

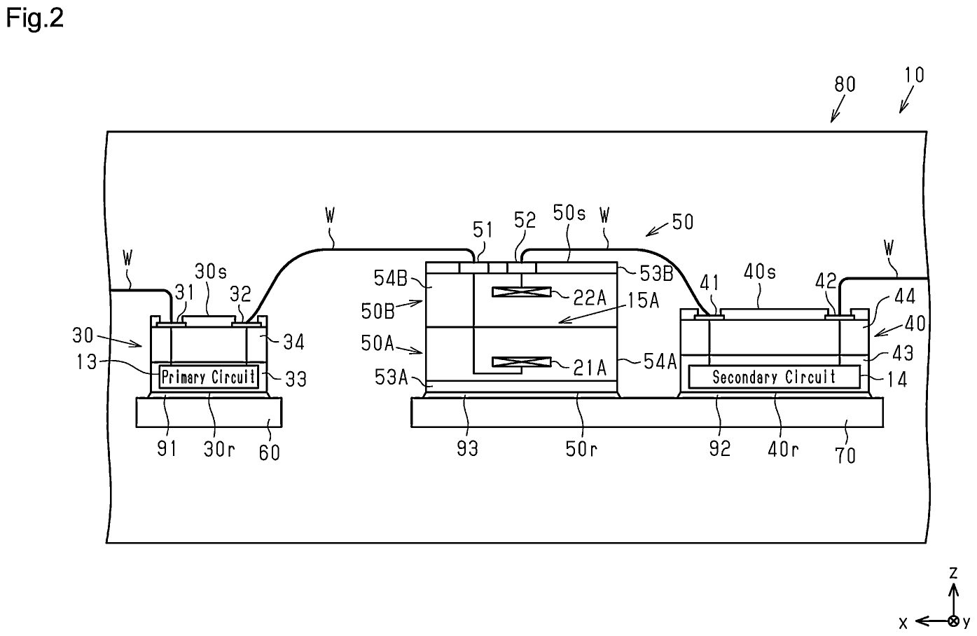

The schematic configuration of a first embodiment of a signal transmission device 10 will now be described with reference to FIGS. 1 and 2. FIG. 1 is a simplified diagram showing an example of the circuit configuration of the signal transmission device 10. FIG. 2 is a schematic cross-sectional structure showing an example of the internal structure of a portion of the signal transmission device 10. For clarity, FIG. 2 does not show hatching lines.

As shown in FIG. 1, the signal transmission device 10 transmits a pulse signal while electrically insulating primary terminals 11 from secondary terminals 12. The signal transmission device 10 is, for example, a digital isolator. The digital isolator is, for example, a DC/DC converter. The signal transmission device 10 includes a signal transmission circuit 10A that includes a primary circuit 13 electrically connected to the primary terminal 11, a secondary circuit 14 electrically connected to the secondary terminal 12, and a transformer 15 electrically insulating the primary circuit 13 from the secondary circuit 14. In the present embodiment, the primary circuit 13 corresponds to a “first circuit,” and the secondary circuit 14 corresponds to a “second circuit.”

The primary circuit 13 is configured to be actuated by application of a first voltage V1. In an example, the primary circuit 13 is electrically connected to an external controller (not shown).

The secondary circuit 14 is configured to be actuated by application of a second voltage V2 that differs from the first voltage V1. The second voltage V2 is, for example, greater than the first voltage V1. The first voltage V1 and the second voltage V2 are direct current voltages. In an example, the secondary circuit 14 is electrically connected to a drive circuit that is a subject controlled by the controller. An example of the drive circuit is a switching circuit.

In the signal transmission circuit 10A, when the primary circuit 13 receives a control signal from the controller via the primary terminal 11, the primary circuit 13 transmits a signal to the secondary circuit 14 via the transformer 15. The signal transmitted to the secondary circuit 14 is then output from the secondary circuit 14 to the drive circuit via the secondary terminal 12.

As described above, in the signal transmission circuit 10A, the primary circuit 13 and the secondary circuit 14 are electrically insulated by the transformer 15. More specifically, while restricting transmission of a direct current voltage between the primary circuit 13 and the secondary circuit 14, the transformer 15 allows transmission of a pulse signal.

That is, the state in which the primary circuit 13 and the secondary circuit 14 are insulated refers to a state in which transmission of a direct current voltage between the primary circuit 13 and the secondary circuit 14 is blocked, whereas transmission of a pulse signal from the primary circuit 13 to the secondary circuit 14 is allowed. Thus, the secondary circuit 14 is configured to receive a signal from the primary circuit 13.

The insulation withstand voltage of the signal transmission device 10 is, for example, in a range of 2500 Vrms to 7500 Vrms. In the present embodiment, the insulation withstand voltage of the signal transmission device 10 is approximately 5700 Vrms. However, the insulation withstand voltage of the signal transmission device 10 is not limited to these values and may be any specific numerical value. In the present embodiment, the primary circuit 13 and the secondary circuit 14 are individually provided with ground.

The structure of the signal transmission device 10 will now be described in detail.

In the present embodiment, the signal transmission device 10 includes two transformers 15 corresponding to two types of signals transmitted from the primary circuit 13 toward the secondary circuit 14. More specifically, the signal transmission device 10 includes a transformer 15 that is used to transmit a first signal from the primary circuit 13 to the secondary circuit 14 and a transformer 15 that is used to transmit a second signal from the primary circuit 13 to the secondary circuit 14. In the present embodiment, the first signal includes information about a rising edge of an external signal that is input to the signal transmission device 10. The second signal includes information about a falling edge of the external signal. The first signal and the second signal generate a pulse signal.

Hereinafter, for the sake of brevity, the transformer 15 used to transmit the first signal is referred to as a “transformer 15A.” The transformer 15 used to transmit the second signal is referred to as a “transformer 15B.” In the present embodiment, the transformer 15A corresponds to a “first signal transformer.” The transformer 15B corresponds to a “second signal transformer.”

The signal transmission device 10 includes a primary signal line 16A connecting the primary circuit 13 to the transformer 15A, a primary signal line 16B connecting the primary circuit 13 to the transformer 15B, a secondary signal line 17A connecting the transformer 15A to the secondary circuit 14, and a secondary signal line 17B connecting the transformer 15B to the secondary circuit 14. The primary signal line 16A transmits the first signal from the primary circuit 13 to the transformer 15A. The primary signal line 16B transmits the second signal from the primary circuit 13 to the transformer 15B. The secondary signal line 17A transmits the first signal from the transformer 15A to the secondary circuit 14. The secondary signal line 17B transmits the second signal from the transformer 15B to the secondary circuit 14. As described above, the first signal is transmitted from the primary circuit 13 to the secondary circuit 14 sequentially through the primary signal line 16A, the transformer 15A, and the secondary signal line 17A. The second signal is transmitted from the primary circuit 13 to the secondary circuit 14 sequentially through the primary signal line 16B, the transformer 15B, and the secondary signal line 17B.

While transmitting the first signal from the primary circuit 13 to the secondary circuit 14, the transformer 15A electrically insulates the primary circuit 13 from the secondary circuit 14. While transmitting the second signal from the primary circuit 13 to the secondary circuit 14, the transformer 15B electrically insulates the primary circuit 13 from the secondary circuit 14.

In the present embodiment, the insulation withstand voltage of the transformers 15A and 15B is in a range of, for example, 2500 Vrms to 7500 Vrms. The insulation withstand voltage of the transformers 15A and 15B may be in a range of 2500 Vrms to 5700 Vrms. However, the insulation withstand voltage of the transformers 15A and 15B is not limited to those values and may be any specific numerical value.

The transformer 15A includes a low-voltage coil 21A and a high-voltage coil 22A electrically insulated from the low-voltage coil 21A and configured to be magnetically coupled to the low-voltage coil 21A.

The low-voltage coil 21A is connected to the primary circuit 13 by the primary signal line 16A and is also connected to the ground of the primary circuit 13. More specifically, the low-voltage coil 21A includes a first end electrically connected to the primary circuit 13 and a second end electrically connected to the ground of the primary circuit 13.

The high-voltage coil 22A is connected to the secondary circuit 14 by the secondary signal line 17A and is also connected to the ground of the secondary circuit 14. More specifically, the high-voltage coil 22A includes a first end electrically connected to the secondary circuit 14 and a second end electrically connected to the ground of the secondary circuit 14.

The transformer 15B includes a low-voltage coil 21B and a high-voltage coil 22B electrically insulated from the low-voltage coil 21B and configured to be magnetically coupled to the low-voltage coil 21B. As shown in FIG. 1, the connection configuration of the low-voltage coil 21B and the high-voltage coil 22B is the same as that of the low-voltage coil 21A and the high-voltage coil 22B and thus will not be described in detail. In the present embodiment, the low-voltage coils 21A and 21B each correspond to a “first insulation element” and a “first coil.” The high-voltage coils 22A and 22B each correspond to a “second insulation element” and a “second coil.”

As shown in FIG. 2, the signal transmission device 10 is a semiconductor device including multiple semiconductor chips arranged in a single package. Although not shown in the drawing, the package of the signal transmission device 10 is, for example, of a small outline (SO) type and, in the present embodiment, is a small outline package (SOP). The package type of the signal transmission device 10 may be changed in any manner.

The signal transmission device 10 includes a first chip 30, a second chip 40, and a transformer chip 50, which are semiconductor chips. The signal transmission device 10 further includes a primary die pad 60 on which the first chip 30 is mounted, a secondary die pad 70 on which the second chip 40 is mounted, and an encapsulation resin 80 encapsulating the die pads 60 and 70 and the chips 30, 40, and 50. In the present embodiment, the transformer chip 50 corresponds to an “insulating chip.” The primary die pad 60 corresponds to a “first die pad.” The secondary die pad 70 corresponds to a “second die pad.”

The encapsulation resin 80 is formed from an electrically-insulative material. An example of such a material is a black epoxy resin. The encapsulation resin 80 has the form of a rectangular plate having a thickness-wise direction aligned with the z-direction.

The primary die pad 60 and the secondary die pad 70 are each flat. The primary die pad 60 and the secondary die pad 70 are each formed from a conductive material. In the present embodiment, the die pads 60 and 70 are formed from a material including copper (Cu). Alternatively, the die pads 60 and 70 may be formed from a material including other metal such as aluminum (Al). Furthermore, the material of the die pads 60 and 70 is not limited to a conductive material. In an example, the die pads 60 and 70 may be formed from ceramics such as alumina. That is, the die pads 60 and 70 may be formed from an electrically-insulative material.

As viewed in the z-direction, the primary die pad 60 and the secondary die pad 70 are separated from each other and arranged next to each other. As viewed in the z-direction, the arrangement direction of the primary die pad 60 and the secondary die pad 70 is referred to as an x-direction. As viewed in the z-direction, a direction orthogonal to the x-direction is referred to as a y-direction.

In the present embodiment, the transformer chip 50 is mounted on the secondary die pad 70. Thus, the transformer chip 50 and the second chip 40 are mounted on the secondary die pad 70. The transformer chip 50 and the second chip 40 are separated from each other in the x-direction on the secondary die pad 70. Thus, the chips 30, 40, and 50 are separated from each other in the x-direction. In the present embodiment, the chips 30, 40, and 50 are arranged in the x-direction from the primary die pad 60 toward the secondary die pad 70 in the order of the first chip 30, the transformer chip 50, and the second chip 40. In other words, the transformer chip 50 is located between the first chip 30 and the second chip 40 in the x-direction.

The die pads 60 and 70 need to be separated from each other so that the signal transmission device 10 is set to a predetermined insulation withstand voltage. In the present embodiment, as viewed in the z-direction, the distance between the primary die pad 60 and the secondary die pad 70 in the x-direction is greater than the distance between the second chip 40 and the transformer chip 50 in the x-direction. Accordingly, as viewed in the z-direction, the distance between the first chip 30 and the transformer chip 50 in the x-direction is greater than the distance between the second chip 40 and the transformer chip 50 in the x-direction. In other words, the transformer chip 50 is located closer to the second chip 40 than to the first chip 30.

The first chip 30 includes a chip head surface 30s and a chip back surface 30r that face opposite directions in the z-direction. The chip back surface 30r faces the primary die pad 60. For the sake of brevity, a direction from the chip back surface 30r toward the chip head surface 30s is referred to as an upward direction, and a direction from the chip head surface 30s toward the chip back surface 30r is referred to as a downward direction.

First electrode pads 31 and second electrode pads 32 are disposed on the chip head surface 30s of the first chip 30 and exposed from the chip head surface 30s.

The first chip 30 includes a first substrate 33 in which the primary circuit 13 is formed. The first substrate 33 is, for example, a semiconductor substrate. In an example, the semiconductor substrate is formed from a material including silicon (Si). An interconnect layer 34 is formed on the first substrate 33. The first substrate 33 includes the chip back surface 30r. The interconnect layer 34 includes the chip head surface 30s.

The interconnect layer 34 includes, for example, insulation films stacked in the z-direction and metal layers arranged between ones of the insulation films that are adjacent to each other in the z-direction. The metal layers form a wiring pattern of the first chip 30. The metal layers are, for example, electrically connected to the primary circuit 13 and the electrode pads 31 and 32. That is, the electrode pads 31 and 32 are electrically connected to the primary circuit 13 by the interconnect layer 34. The metal layers are formed from a material including, for example, Cu, Al, or the like.

The first chip 30 is bonded to the primary die pad 60 by a first bonding material 91. The first bonding material 91 is in contact with the chip back surface 30r and the primary die pad 60. The first bonding material 91 is a conductive bonding material such as solder or silver (Ag) paste. This electrically connects the first substrate 33 to the primary die pad 60. The primary die pad 60 includes a ground. Thus, the primary circuit 13 is electrically connected to the ground.

The second chip 40 includes a chip head surface 40s and a chip back surface 40r that face opposite directions in the z-direction. The chip head surface 40s faces the same direction as the chip head surface 30s of the first chip 30. The chip back surface 40r faces the same direction as the chip back surface 30r of the first chip 30. Thus, the chip back surface 40r faces the secondary die pad 70.

First electrode pads 41 and second electrode pads 42 are disposed on the chip head surface 40s of the second chip 40 and exposed from the chip head surface 40s.

The second chip 40 includes a second substrate 43 on which the secondary circuit 14 is formed. The second substrate 43 is, for example, a semiconductor substrate. In an example, the semiconductor substrate is formed from a material including Si. An interconnect layer 44 is formed on the second substrate 43. The second substrate 43 includes the chip back surface 40r. The interconnect layer 44 includes the chip head surface 40s.

The interconnect layer 44 includes insulation films and metal layers in the same manner as the interconnect layer 34. The metal layers form a wiring pattern of the second chip 40. The metal layers are, for example, electrically connected to the secondary circuit 14 and the electrode pads 41 and 42. That is, the electrode pads 41 and 42 are electrically connected to the secondary circuit 14 by the interconnect layer 44.

The second chip 40 is bonded to the secondary die pad 70 by a second bonding material 92. The second bonding material 92 is in contact with the chip back surface 40r and the secondary die pad 70. The second bonding material 92 is a conductive bonding material. Thus, the second substrate 43 is electrically connected to the secondary die pad 70. The secondary die pad 70 includes a ground. Thus, the secondary circuit 14 is electrically connected to the ground.

The transformer chip 50 is the transformers 15A and 15B (refer to FIG. 1) that are integrated in a single chip. More specifically, the transformer chip 50 is separate from the first chip 30 and the second chip 40 and is dedicated to the transformers 15A and 15B. The transformer chip 50 includes a chip head surface 50s and a chip back surface 50r that face opposite directions in the z-direction. The chip head surface 50s faces the same direction as the chip head surface 40s of the second chip 40. The chip back surface 50r faces the same direction as the chip back surface 40r of the second chip 40.

First electrode pads 51 and second electrode pads 52 are disposed on the chip head surface 50s of the transformer chip 50 and exposed from the chip head surface 50s. The first electrode pads 51 are configured to be electrically connected to the low-voltage coil 21A (21B). The second electrode pads 52 are configured to be electrically connected to the high-voltage coil 22A (22B).

The transformer chip 50 is bonded to the secondary die pad 70 by a third bonding material 93 when the chip back surface 50r faces the secondary die pad 70. The third bonding material 93 is in contact with the chip back surface 50r and the secondary die pad 70. The third bonding material 93 is an insulative bonding material such as an epoxy resin.

The first electrode pads 31 of the first chip 30 are separately connected by wires W to primary leads, which are not shown. The primary leads are parts forming the primary terminals 11 shown in FIG. 1. Thus, the primary circuit 13 is electrically connected to the primary terminals 11. The primary leads include portions projecting outward from the encapsulation resin 80.

The second electrode pads 32 of the first chip 30 are separately connected to the first electrode pads 51 of the transformer chip 50 by wires W. Thus, the primary circuit 13 is electrically connected to the low-voltage coil 21A (21B).

The second electrode pads 52 of the transformer chip 50 are separately connected to the first electrode pads 41 of the second chip 40 by wires W. Thus, the high-voltage coil 22A (22B) is electrically connected to the secondary circuit 14.

The second electrode pads 42 of the second chip 40 are separately connected by wires W to secondary leads, which are not shown. The secondary leads are parts forming the secondary terminals 12 shown in FIG. 1. Thus, the secondary circuit 14 is electrically connected to the secondary terminals 12. The secondary leads include portions projecting outward from the encapsulation resin 80. The wires W described above are bonding wires formed by a wire bonder. Each wire W is formed of a conductor such as, for example, gold (Au), Al, or Cu.

### Schematic Structure of Transformer Chip

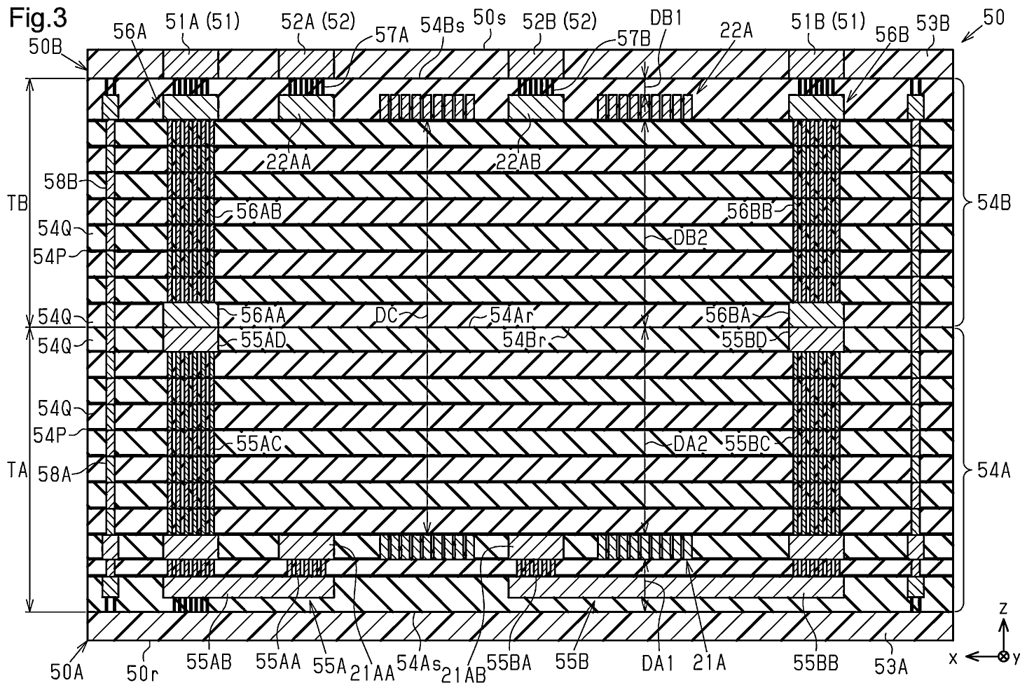

An example of the internal structure of the transformer chip 50 will now be described with reference to FIG. 3. FIG. 3 is a schematic cross-sectional view showing a cross-sectional structure of the transformer chip 50 taken along the xz-plane. To facilitate understanding, the cross-sectional structure of the transformer chip 50 shown in FIG. 2 is simplified in the cross-sectional structure of the transformer chip 50 shown in FIG. 3. Thus, the cross-sectional structure of the transformer chip 50 shown in FIG. 3 differs from the cross-sectional structure of the transformer chip 50 shown in FIG. 2. FIG. 3 shows the transformer 15A. In the transformer chip 50, the transformer 15B and the transformer 15A have the same structure.

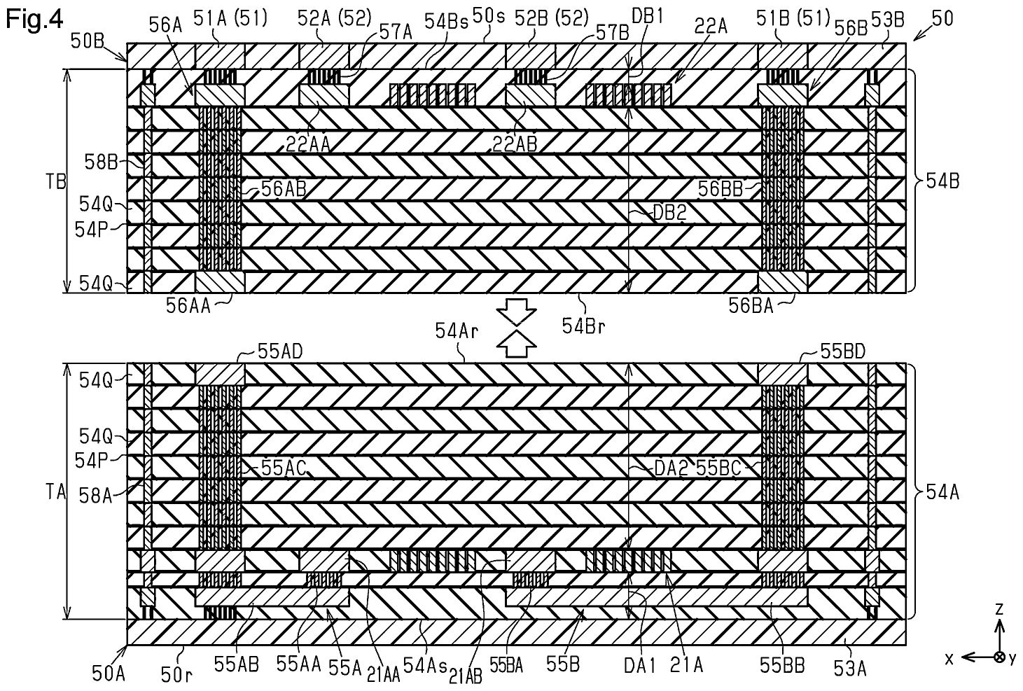

As shown in FIG. 3, in the transformer chip 50, a second unit 50B is disposed on a first unit 50A. The transformer chip 50 has a structure in which the first unit 50A is adhered to the second unit 50B. FIG. 4 is a cross-sectional structure of the first unit 50A and the second unit 50B that are separated from each other. FIGS. 3 and 4 are used as references in the following description.

### First Unit

The first unit 50A is a unit of the transformer chip 50 that is bonded to the secondary die pad 70 by the third bonding material 93 (refer to FIG. 2). The first unit 50A includes a first substrate 53A and a first element insulation layer 54A formed on the first substrate 53A.

The first substrate 53A includes the chip back surface 50r of the transformer chip 50. The first substrate 53A is formed of, for example, a semiconductor substrate. In the present embodiment, the first substrate 53A is a semiconductor substrate formed from a material including Si. As the semiconductor substrate of the first substrate 53A, a wide-bandgap semiconductor or a compound semiconductor may be used. Instead of a semiconductor substrate, the first substrate 53A may be an insulating substrate that is formed from a material including glass or an insulating substrate that is formed from a material including ceramics such as alumina.

The wide-bandgap semiconductor is a semiconductor substrate having a band gap that is greater than or equal to 2.0 eV. The wide-bandgap semiconductor may be silicon carbide (SiC). The compound semiconductor may be a group III-V compound semiconductor. The compound semiconductor may include at least one of aluminum nitride (AIN), indium nitride (InN), gallium nitride (GaN), and gallium arsenide (GaAs).

The first element insulation layer 54A includes etching stopper films 54P and interlayer insulation films 54Q. The etching stopper films 54P and the interlayer insulation films 54Q are alternately stacked on one another in the z-direction. That is, the interlayer insulation film 54Q is formed on the etching stopper film 54P. The z-direction may be referred to as “thickness-wise direction of first element insulation layer.” In the present embodiment, the etching stopper film 54P corresponds to a “first insulation film”. The interlayer insulation film 54Q corresponds to a “second insulation film.”

The etching stopper film 54P is formed from a material including silicon nitride (SiN), SiC, nitrogen-doped silicon carbide (SiCN), or the like. In the present embodiment, the etching stopper film 54P is formed from a material including SiN. The etching stopper film 54P, for example, inhibits diffusion of Cu. That is, the etching stopper film 54P is a Cu diffusion barrier film.

The interlayer insulation film 54Q is an oxide film formed from a material including silicon oxide (SiO₂). The interlayer insulation film 54Q is greater in thickness than the etching stopper film 54P. The etching stopper film 54P has a thickness that is greater than or equal to 50 nm and less than 1000 nm. The interlayer insulation film 54Q has a thickness that is greater than or equal to 500 nm and less than or equal to 5000 nm. In the present embodiment, the thickness of the etching stopper film 54P is approximately 300 nm. The thickness of the interlayer insulation film 54Q is approximately 2000 nm. In the drawings, to aid understanding, the ratio of the thickness of the etching stopper film 54P to the thickness of the interlayer insulation film 54Q differs from the actual ratio of the thickness of the etching stopper film 54P to the thickness of the interlayer insulation film 54Q.

The first element insulation layer 54A includes a first element head surface 54As and a first element back surface 54Ar that face opposite sides in the z-direction. The first element head surface 54As and the chip back surface 50r of the transformer chip 50 face the same direction. The first element back surface 54Ar and the chip head surface 50s of the transformer chip 50 face the same direction. In the present embodiment, the first element head surface 54As of the first element insulation layer 54A is in contact with the first substrate 53A. That is, the first substrate 53A is formed on the first element head surface 54As. The first element back surface 54Ar is formed of the interlayer insulation film 54Q.

The first unit 50A includes the low-voltage coil 21A embedded in the first element insulation layer 54A. The low-voltage coil 21A is arranged at a position separated from the first element back surface 54Ar in the z-direction.

More specifically, the low-voltage coil 21A is disposed closer to the first element head surface 54As than a center of the first element insulation layer 54A between the first element head surface 54As and the first element back surface 54Ar in the z-direction. That is, the low-voltage coil 21A is disposed closer to the first element head surface 54As than the center of the first element insulation layer 54A in the thickness-wise direction (z-direction).

In other words, the low-voltage coil 21A and the second unit 50B are disposed at opposite sides of the center of the first element insulation layer 54A in the thickness-wise direction (z-direction). Therefore, a distance DA1 between the low-voltage coil 21A and the first element head surface 54As in the z-direction is less than a distance DA2 between the low-voltage coil 21A and the first element back surface 54Ar in the z-direction. In an example, the distance DA1 is less than or equal to ½ of the distance DA2. In an example, the distance DA1 is less than or equal to ⅓ of the distance DA2. In an example, the distance DA1 is greater than or equal to ¼ of the distance DA2. The distances DA1 and DA2 may each be changed in any manner.

The low-voltage coil 21A includes a first end 21AA and a second end 21AB. As viewed in the z-direction, the first end 21AA is located outward from the windings of the low-voltage coil 21A. As viewed in the z-direction, the second end 21AB is located inward from the windings of the low-voltage coil 21A. As viewed in the z-direction, the low-voltage coil 21A is spiral. The number of windings in the high-voltage coil 22A may be changed in any manner.

The first unit 50A includes first connection electrodes 55A and 55B electrically connected to the low-voltage coil 21A.

The first connection electrode 55A is electrically connected to the first end 21AA of the low-voltage coil 21A. The first connection electrode 55A includes a first via 55AA connected to the first end 21AA, an interconnect 55AB connected to the first via 55AA and extending in the x-direction, a second via 55AC connected to the interconnect 55AB and extending in the z-direction, and an electrode portion 55AD connected to the second via 55AC. The first connection electrode 55A is electrically connected to the first substrate 53A. Thus, the first end 21AA of the low-voltage coil 21A is electrically connected to the first substrate 53A. In the present embodiment, the first end 21AA of the low-voltage coil 21A is electrically connected to the ground of the primary circuit 13 (refer to FIG. 1). In the present embodiment, the interconnect 55AB is disposed closer to the first substrate 53A than the low-voltage coil 21A. The electrode portion 55AD is exposed from the first element back surface 54Ar.

The first connection electrode 55B is electrically connected to the second end 21AB of the low-voltage coil 21A. The first connection electrode 55B includes a first via 55BA, an interconnect 55BB, a second via 55BC, and an electrode portion 55BD in the same manner as the first connection electrode 55B. The first via 55BA is connected to the second end 21AB. In the present embodiment, the interconnect 55BB is disposed closer to the first substrate 53A than the low-voltage coil 21A. The interconnect 55BB is aligned with the interconnect 55AB in the z-direction. The electrode portion 55BD is exposed from the first element back surface 54Ar. Thus, the first connection electrodes 55A and 55B are disposed in the first element insulation layer 54A and exposed from the first element back surface 54Ar.

The first unit 50A includes a first shield electrode 58A. The first shield electrode 58A limits entrance of moisture into the first element insulation layer 54A and formation of cracks in the first element insulation layer 54A. In plan view, the first shield electrode 58A is formed to surround the low-voltage coils 21A and 21B and the first connection electrodes 55A and 55B. The first shield electrode 58A extends through the first element insulation layer 54A in the z-direction. The first shield electrode 58A is electrically connected to the first substrate 53A. The first shield electrode 58A is disposed in the first element insulation layer 54A and exposed from the first element back surface 54Ar.

Each of the low-voltage coil 21A, the first connection electrodes 55A and 55B, and the first shield electrode 58A is formed from one or more materials including titanium (Ti), titanium nitride (TiN), tantalum (Ta), tantalum nitride (TaN), Au, Ag, Cu, Al, and tungsten (W). In the present embodiment, each of the low-voltage coil 21A, the first connection electrodes 55A and 55B, and the first shield electrode 58A is formed from a material including Cu. In the present embodiment, a coil groove is arranged in the first element insulation layer 54A and is filled with a material including a barrier metal and Cu to form the low-voltage coil 21A. In the same manner as the low-voltage coil 21A, the first connection electrodes 55A and 55B and the first shield electrode 58A are formed from a material including barrier metal and Cu.

Although not shown in the drawing, the low-voltage coil 21B (refer to FIG. 1) and a first connection electrode electrically connected to the low-voltage coil 21B are embedded in the first element insulation layer 54A. The low-voltage coil 21B is aligned with the low-voltage coil 21A in the z-direction. The low-voltage coil 21B is separated from the low-voltage coil 21A in the y-direction. In the present embodiment, a member that is embedded in the first element insulation layer 54A and formed from a material including Cu such as the low-voltage coil 21B is formed from a material including a barrier metal and Cu in the same manner as the low-voltage coil 21A.

### Second Unit

The second unit 50B is a unit of the transformer chip 50 that is disposed on the first unit 50A. The second unit 50B includes a second substrate 53B and a second element insulation layer 54B formed on the second substrate 53B. In the present embodiment, the second substrate 53B is formed on the second element insulation layer 54B.

The second substrate 53B includes the chip head surface 50s of the transformer chip 50. The second substrate 53B is formed of, for example, a semiconductor substrate. In the present embodiment, the second substrate 53B is a semiconductor substrate formed from a material including Si in the same manner as the first substrate 53A. As the semiconductor substrate of the second substrate 53B, a wide-bandgap semiconductor or a compound semiconductor may be used. Instead of a semiconductor substrate, the second substrate 53B may be an insulating substrate that is formed from a material including glass or an insulating substrate that is formed from a material including ceramics such as alumina.

The second element insulation layer 54B includes etching stopper films 54P and interlayer insulation films 54Q. The etching stopper films 54P and the interlayer insulation films 54Q are alternately stacked on one another in the z-direction. That is, the interlayer insulation film 54Q is formed on the etching stopper film 54P. The z-direction may be referred to as “thickness-wise direction of second element insulation layer.” As described above, the first element insulation layer 54A and the second element insulation layer 54B each include the etching stopper film 54P corresponding to a first insulation film and the interlayer insulation film 54Q corresponding to a second insulation film.

The second element insulation layer 54B includes a second element head surface 54Bs and a second element back surface 54Br that face opposite sides in the z-direction. The second element head surface 54Bs and the chip head surface 50s of the transformer chip 50 face the same direction. The second element back surface 54Br and the chip back surface 50r of the transformer chip 50 face the same direction. In the present embodiment, the second element head surface 54Bs of the second element insulation layer 54B is in contact with the second substrate 53B. That is, the second substrate 53B is formed on the second element head surface 54Bs. The second element back surface 54Br is formed of the interlayer insulation film 54Q. The second element back surface 54Br faces the first element back surface 54Ar of the first element insulation layer 54A.

In the present embodiment, a thickness TB of the second element insulation layer 54B is less than a thickness TA of the first element insulation layer 54A. More specifically, the thickness TA of the first element insulation layer 54A is greater than the thickness TB of the second element insulation layer 54B in correspondence with the interconnects 55AB and 55BB of the first connection electrodes 55A and 55B being disposed below the low-voltage coil 21A.

The thickness TB of the second element insulation layer 54B may be equal to the thickness TA of the first element insulation layer 54A. The thickness TA of the first element insulation layer 54A is defined by the distance between the first element head surface 54As and the first element back surface 54Ar in the z-direction. The thickness TB of the second element insulation layer 54B is defined by the distance between the second element head surface 54Bs and the second element back surface 54Br in the z-direction. When the difference between the thickness TB of the second element insulation layer 54B and the thickness TA of the first element insulation layer 54A is, for example, within 20% of the thickness TA of the first element insulation layer 54A, it is considered that the thickness TB of the second element insulation layer 54B is equal to the thickness TA of the first element insulation layer 54A. In an example, the thickness TA may be less than the thickness TB.

The second unit 50B includes the high-voltage coil 22A embedded in the second element insulation layer 54B. The high-voltage coil 22A is arranged at a position separated from the second element back surface 54Br in the z-direction.

More specifically, the high-voltage coil 22A is disposed closer to the second element head surface 54Bs than a center of the second element insulation layer 54B between the second element head surface 54Bs and the second element back surface 54Br in the z-direction. That is, the high-voltage coil 22A is disposed closer to the second element head surface 54Bs than the center of the second element insulation layer 54B in the thickness-wise direction (z-direction). In other words, the high-voltage coil 22A and the first unit 50A are disposed at opposite sides of the center of the second element insulation layer 54B in the thickness-wise direction (z-direction). Therefore, a distance DB1 between the high-voltage coil 22A and the second element head surface 54Bs in the z-direction is less than a distance DB2 between the high-voltage coil 22A and the second element back surface 54Br in the z-direction. In an example, the distance DB1 is less than or equal to ½ of the distance DB2. In an example, the distance DB1 is less than or equal to ⅓ of the distance DB2. The distance DB1 is less than or equal to ⅕ of the distance DB2. The distance DB1 is less than or equal to 1/10 of the distance DB2. In an example, the distance DB1 is greater than or equal to 1/11 of the distance DB2. The distances DB1 and DB2 may each be changed in any manner.

In the present embodiment, the distance DB1 is less than the distance DA1. More specifically, the distance DA1 needs to be greater than the distance DB1 in correspondence with the interconnects 55AB and 55BB of the first connection electrodes 55A and 55B being disposed below the low-voltage coil 21A. In other words, the distance DB1 may be less than the distance DA1 since the second unit 50B does not include interconnects, such as the interconnects 55AB and 55BB, extending over the high-voltage coil 22A between the high-voltage coil 22A and the second element head surface 54Bs.

In the present embodiment, the distance DB2 is equal to the distance DA2. When the difference between the distance DB2 and the distance DA2 is, for example, within 20% of the distance DB2, it is considered that the distance DB2 is equal to the distance DA2. As described above, the etching stopper films 54P and the interlayer insulation films 54Q arranged between the high-voltage coil 22A and the second element back surface 54Br in the second element insulation layer 54B is equal in number to the etching stopper films 54P and the interlayer insulation films 54Q arranged between the low-voltage coil 21A and the first element back surface 54Ar in the first element insulation layer 54A. The distances DA2 and DB2 may each be changed in any manner. In an example, the distance DA2 may be greater than the distance DB2. The distance DB2 may be greater than the distance DA2.

The high-voltage coil 22A includes a first end 22AA and a second end 22AB. As viewed in the z-direction, the first end 22AA is located outward from the windings of the high-voltage coil 22A. As viewed in the z-direction, the second end 22AB is located inward from the windings of the high-voltage coil 22A. As viewed in the z-direction, the high-voltage coil 22A is spiral. The high-voltage coil 22A and the low-voltage coil 21A are wound the same number of times. The number of windings in the high-voltage coil 22A may be changed in any manner.

The second unit 50B includes the first electrode pads 51, the second electrode pads 52, and second connection electrodes 56A and 56B arranged in the second element insulation layer 54B.

The first electrode pads 51 and the second electrode pads 52 are arranged on the second substrate 53B. The first electrode pads 51 and the second electrode pads 52 are each configured as a Si through-electrode (through-silicon via; “TSV”). Thus, the first electrode pads 51 and the second electrode pads 52 are each exposed from the second substrate 53B. As described above, the second substrate 53B includes the first electrode pads 51 and the second electrode pads 52 as external electrodes.

In the present embodiment, the first electrode pads 51 include two first electrode pads 51A and 51B electrically connected to the low-voltage coil 21A. The second electrode pads 52 include two second electrode pads 52A and 52B electrically connected to the high-voltage coil 22A.

The second connection electrode 56A is electrically connected to the first electrode pad 51A. The second connection electrode 56A includes an electrode portion 56AA and a via 56AB connected to the electrode portion 56AA and extending in the z-direction. The electrode portion 56AA is exposed from the second element back surface 54Br. The via 56AB is connected to the first electrode pad 51A.

The second connection electrode 56B is electrically connected to the first electrode pad 51B. The second connection electrode 56B includes an electrode portion 56BA and a via 56BB in the same manner as the second connection electrode 56A. The electrode portion 56BA is exposed from the second element back surface 54Br. The via 56BB is connected to the first electrode pad 51B. Thus, the second connection electrodes 56A and 56B are disposed in the second element insulation layer 54B and exposed from the second element back surface 54Br.

The second unit 50B includes a second shield electrode 58B. The second shield electrode 58B limits entrance of moisture into the second element insulation layer 54B and formation of cracks in the second element insulation layer 54B. The second shield electrode 58B is formed to surround the high-voltage coils 22A and 22B and the second connection electrodes 56A and 56B. The second shield electrode 58B extends through the second element insulation layer 54B in the z-direction. The second shield electrode 58B is electrically connected to the second substrate 53B. The second shield electrode 58B is disposed in the second element insulation layer 54B and exposed from the second element back surface 54Br.

The first end 22AA of the high-voltage coil 22A is electrically connected to the second electrode pad 52A by a via 57A. The second electrode pad 52A overlaps the first end 22AA as viewed in the z-direction. The via 57A connects the second electrode pad 52A and the first end 22AA in the z-direction.

The second end 22AB of the high-voltage coil 22A is electrically connected to the second electrode pad 52B by a via 57B. The second electrode pad 52B overlaps the second end 22AB in the z-direction. The via 57B connects the second electrode pad 52B and the second end 22AB in the z-direction.

The high-voltage coil 22A, the second connection electrodes 56A and 56B, the vias 57A and 57B, and the second shield electrode 58B are each formed from one or more materials including, for example, Ti, TiN, Ta, TaN, Au, Ag, Cu, Al, and W. In the present embodiment, each of the high-voltage coil 22A, the second connection electrodes 56A and 56B, the vias 57A and 57B, and the second shield electrode 58B are formed from a material including Cu in the same manner as the low-voltage coil 21A, the first connection electrodes 55A and 55B, and the first shield electrode 58A. In the present embodiment, a coil groove is arranged in the second element insulation layer 54B and is filled with a material including a barrier metal and Cu to form the high-voltage coil 22A in the same manner as the low-voltage coil 21A. The second connection electrodes 56A and 56B and the second shield electrode 58B are formed from a material including a barrier metal and Cu in the same manner as the high-voltage coil 22A.

The first electrode pads 51 and the second electrode pads 52 are each formed from one or more materials including, for example, Ti, TiN, Ta, TaN, Au, Ag, Cu, Al, and W. In the present embodiment, the first electrode pads 51 and the second electrode pads 52 are formed from a material including Cu.

Although not shown in the drawing, the high-voltage coil 22B (refer to FIG. 1) and a via electrically connected to the high-voltage coil 22B are embedded in the second element insulation layer 54B. The high-voltage coil 22B is aligned with the high-voltage coil 22A in the z-direction. The high-voltage coil 22B is separated from the high-voltage coil 22A in the y-direction. In the present embodiment, a member that is embedded in the second element insulation layer 54B and formed from a material including Cu such as the high-voltage coil 22B is formed from a material including a barrier metal and Cu in the same manner as the high-voltage coil 22A.

### Bonding of First Unit and Second Unit

The first unit 50A and the second unit 50B are disposed so that the first element back surface 54Ar of the first element insulation layer 54A in the first unit 50A is in contact with the second element back surface 54Br of the second element insulation layer 54B in the second unit 50B. In this state, the first connection electrode 55A is electrically connected to the second connection electrode 56A, and the first connection electrode 55B is electrically connected to the second connection electrode 56B. Also, the first shield electrode 58A is electrically connected to the second shield electrode 58B.

More specifically, when the first element back surface 54Ar of the first element insulation layer 54A is in contact with the second element back surface 54Br of the second element insulation layer 54B, the electrode portion 55AD of the first connection electrode 55A and the electrode portion 56AA of the second connection electrode 56A face each other in the z-direction, and the electrode portion 55BD of the first connection electrode 55B and the electrode portion 56BA of the second connection electrode 56B face each other in the z-direction. In the present embodiment, the electrode portion 55AD (55BD) is in contact with the electrode portion 56AA (56BD). In this state, the electrode portion 55AD (55BD) and the electrode portion 56AA (56BD) are bonded to each other by Cu—Cu bonding. The first connection electrode 55A (55B) and the second connection electrode 56A (56B) are bonded by Cu—Cu bonding. Thus, the first connection electrode 55A (55B) is electrically connected to the second connection electrode 56A (56B). The Cu—Cu bonding may be performed through a known process.

When the first element back surface 54Ar of the first element insulation layer 54A is in contact with the second element back surface 54Br of the second element insulation layer 54B, the first shield electrode 58A and the second shield electrode 58B face each other in the z-direction. In the present embodiment, the first shield electrode 58A is in contact with the second shield electrode 58B. In this state, the first shield electrode 58A and the second shield electrode 58B are bonded by Cu—Cu bonding. Thus, the first shield electrode 58A is electrically connected to the second shield electrode 58B. In the present embodiment, the Cu—Cu bonding of the first connection electrode 55A (55B) and the second connection electrode 56A (56B) and the Cu—Cu bonding of the first shield electrode 58A and the second shield electrode 58B may be performed in the same process. The first element back surface 54Ar is formed of the interlayer insulation film 54Q. The second element back surface 54Br is formed of the interlayer insulation film 54Q. Thus, when the first element back surface 54Ar is in contact with the second element back surface 54Br, the interlayer insulation films 54Q are in contact with each other.

When the first unit 50A is bonded to the second unit 50B, the low-voltage coil 21A is opposed to the high-voltage coil 22A in the z-direction. In the present embodiment, the first end 21AA of the low-voltage coil 21A is opposed to the first end 22AA of the high-voltage coil 22A in the z-direction. The second end 21AB of the low-voltage coil 21A is opposed to the second end 22AB of the high-voltage coil 22A in the z-direction. The positional relationship of the first end 21AA of the low-voltage coil 21A and the first end 22AA of the high-voltage coil 22A and the positional relationship between the second end 21AB of the low-voltage coil 21A and the second end 22AB of the high-voltage coil 22A may be changed in any manner.

A distance DC between the low-voltage coil 21A and the high-voltage coil 22A in the z-direction is greater than each of the thickness TA of the first element insulation layer 54A and the thickness TB of the second element insulation layer 54B. The distance DC is defined by the sum of the distance DA2 and the distance DB2. In an example, the distance DC is greater than or equal to 1.5 times the thickness TA (TB). In another example, the distance DC is less than two times the thickness TA (TB).

### Operation

The operation of the present embodiment will now be described.

An element insulation layer is formed on a Si wafer, which forms a substrate. Then, the Si wafer undergoes singulation using a dicing blade to manufacture a number of semiconductor chips (in the present embodiment, the transformer chip 50). An increase in the thickness of the element insulation layer formed on the Si wafer increases warpage of the Si wafer.

To improve the insulation withstand voltage of a transformer chip, the distance between the low-voltage coil and the high-voltage coil (distance DC in the present embodiment) needs to be increased. However, it is difficult to increase the thickness of the element insulation layer without increasing the warpage of the Si wafer. Accordingly, it is difficult to increase the distance between the low-voltage coil and the high-voltage coil.

In this regard, in the present embodiment, the transformer chip 50 has a structure in which the first unit 50A including the first element insulation layer 54A is bonded to the second unit 50B including the second element insulation layer 54B. More specifically, in the first unit 50A, the first element insulation layer 54A is formed on the first substrate 53A formed of the Si wafer. In the second unit 50B, the second element insulation layer 54B is formed on the second substrate 53B formed of the Si wafer. In other words, the first element insulation layer 54A and the second element insulation layer 54B, which are separately formed, are adhered to each other to form the element insulation layers disposed between the low-voltage coils 21A and 21B and the high-voltage coils 22A and 22B in the z-direction. With this configuration, the distance DC between the low-voltage coils 21A and 21B and the high-voltage coils 22A and 22B in the z-direction is increased without excessively increasing the thicknesses TA and TB of the first element insulation layer 54A and the second element insulation layer 54B. Thus, the insulation withstand voltage of the transformer chip 50 is improved while limiting increases in the warpage of the Si wafer of the first substrate 53A and the warpage of the Si wafer of the second substrate 53B.

### Advantages

The present embodiment has the following advantages.

(1-1) The transformer chip 50 includes the first unit 50A and the second unit 50B disposed on the first unit 50A. The first unit 50A includes the first element insulation layer 54A including the first element back surface 54Ar facing the second unit 50B and the first element head surface 54As opposite to the first element back surface 54Ar, the low-voltage coils 21A and 21B embedded in the first element insulation layer 54A at a position separated from the first element back surface 54Ar in the z-direction, and the first connection electrode 55A disposed in the first element insulation layer 54A and exposed from the first element back surface 54Ar and electrically connected to the low-voltage coils 21A and 21B. The second unit 50B includes the second element insulation layer 54B including the second element back surface 54Br facing the first element back surface 54Ar and the second element head surface 54Bs opposite to the second element back surface 54Br, the high-voltage coils 22A and 22B embedded in the second element insulation layer 54B at a position separated from the second element back surface 54Br in the z-direction and opposed to the low-voltage coils 21A and 21B, and the second connection electrode 56A disposed in the second element insulation layer 54B and exposed from the second element back surface 54Br. The first unit 50A and the second unit 50B are disposed so that the first element back surface 54Ar is in contact with the second element back surface 54Br. The first connection electrode 55A is electrically connected to the second connection electrode 56A.

With this configuration, the first element insulation layer 54A and the second element insulation layer 54B are formed separately. The first element insulation layer 54A and the second element insulation layer 54B are stacked to form an element insulation layer in which the low-voltage coils 21A and 21B and the high-voltage coils 22A and 22B are disposed. This allows for an increase in the distance DC between the low-voltage coils 21A and 21B and the high-voltage coils 22A and 22B in the z-direction. Thus, the insulation withstand voltage of the transformer chip 50 is improved.

(1-2) The low-voltage coils 21A and 21B are disposed closer to the first element head surface 54As than the center of the first element insulation layer 54A in the z-direction. The high-voltage coils 22A and 22B are disposed closer to the second element head surface 54Bs than the center of the second element insulation layer 54B in the z-direction.

This configuration allows for an increase in the distance DC between the low-voltage coils 21A and 21B and the high-voltage coils 22A and 22B. Thus, the insulation withstand voltage of the transformer chip 50 is improved.

(1-3) The distance DC between the low-voltage coils 21A and 21B and the high-voltage coils 22A and 22B is greater than each of the thickness TA of the first element insulation layer 54A and the thickness TB of the second element insulation layer 54B.

With this configuration, the distance DC between the low-voltage coils 21A and 21B and the high-voltage coils 22A and 22B is increased, while avoiding an excessive increase in the thickness TA of the first element insulation layer 54A and the thickness TB of the second element insulation layer 54B. Thus, the transformer chip 50 is readily manufactured, while the insulation withstand voltage of the transformer chip 50 is improved.

(1-4) The first element insulation layer 54A and the second element insulation layer 54B each have a structure in which the etching stopper films 54P and the interlayer insulation films 54Q are alternately stacked on one another.

This configuration reduces the warpage of the first element insulation layer 54A and the warpage of the second element insulation layer 54B. The thicknesses TA and TB of the first element insulation layer 54A and the second element insulation layer 54B are increased within a predetermined warpage amount. This allows for an increase in the distance DC between the low-voltage coils 21A and 21B and the high-voltage coils 22A and 22B.

(1-5) The second unit 50B includes the second substrate 53B disposed on the second element head surface 54Bs of the second element insulation layer 54B. The second substrate 53B includes the first electrode pads 51 and the second electrode pads 52.

With this configuration, the second unit 50B includes the Si wafer forming the second substrate 53B and the element insulation layer (second element insulation layer 54B) disposed on the Si wafer. This eliminates the need for a step for separating the Si wafer from the element insulation layer. Thus, the manufacturing process of the second unit 50B is simplified.

(1-6) The signal transmission device 10 includes the first chip 30 including the primary circuit 13, the transformer chip 50, and the second chip 40 including the secondary circuit 14 configured to receive a signal from the primary circuit 13 through the transformer chip 50. The transformer chip 50 includes the first unit 50A and the second unit 50B disposed on the first unit 50A. The first unit 50A includes the first element insulation layer 54A including the first element back surface 54Ar facing the second unit 50B and the first element head surface 54As opposite to the first element back surface 54Ar, the low-voltage coils 21A and 21B embedded in the first element insulation layer 54A at a position separated from the first element back surface 54Ar in the z-direction, and the first connection electrode 55A disposed in the first element insulation layer 54A and exposed from the first element back surface 54Ar and electrically connected to the low-voltage coils 21A and 21B. The second unit 50B includes the second element insulation layer 54B including the second element back surface 54Br facing the first element back surface 54Ar and the second element head surface 54Bs opposite to the second element back surface 54Br, the high-voltage coils 22A and 22B embedded in the second element insulation layer 54B at a position separated from the second element back surface 54Br in the z-direction and opposed to the low-voltage coils 21A and 21B, and the second connection electrode 56A disposed in the second element insulation layer 54B and exposed from the second element back surface 54Br. The first unit 50A and the second unit 50B are disposed so that the first element back surface 54Ar is in contact with the second element back surface 54Br. The first connection electrode 55A is electrically connected to the second connection electrode 56A.

With this configuration, the first element insulation layer 54A and the second element insulation layer 54B are formed separately. The first element insulation layer 54A and the second element insulation layer 54B are stacked to form an element insulation layer in which the low-voltage coils 21A and 21B and the high-voltage coils 22A and 22B are disposed. This allows for an increase in the distance DC between the low-voltage coils 21A and 21B and the high-voltage coils 22A and 22B in the z-direction. Thus, the insulation withstand voltage of the transformer chip 50 is improved. Accordingly, the insulation withstand voltage of the signal transmission device 10 is improved.

### Second Embodiment

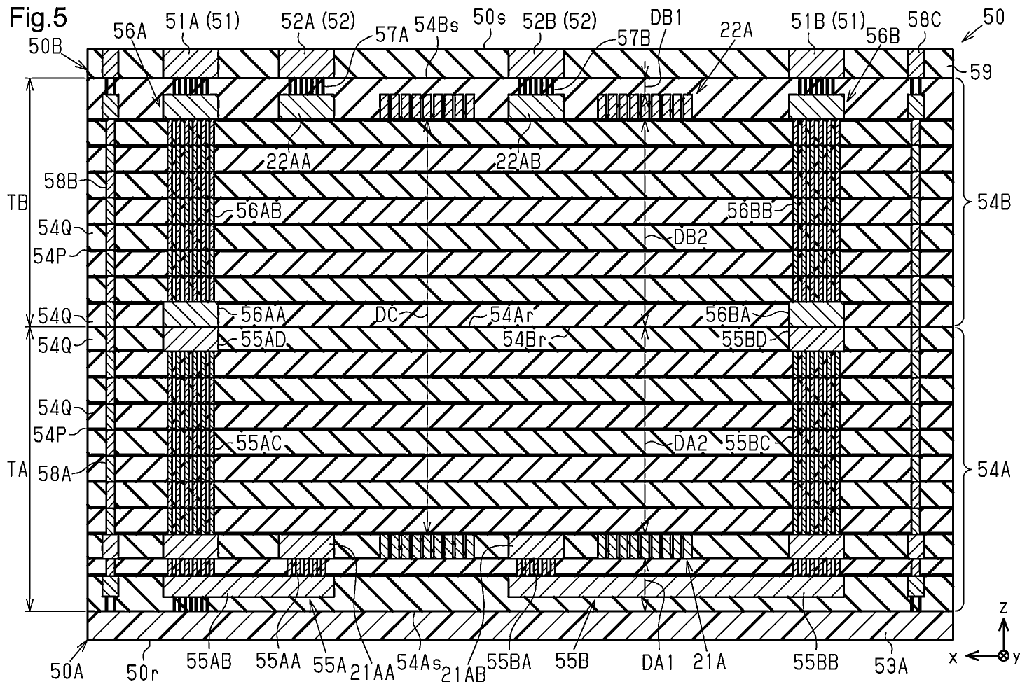

A second embodiment of the transformer chip 50 will now be described with reference to FIG. 5. The transformer chip 50 of the present embodiment differs from the transformer chip 50 of the first embodiment in the structure of the second unit 50B. In the description below, the same reference characters are given to those components that are the same as the corresponding components of the first embodiment. Such components will not be described in detail.

FIG. 5 is a schematic cross-sectional view showing a cross-sectional structure of the transformer chip 50 taken along the xz-plane. FIG. 5 shows the transformer 15A. The structure of the transformer 15B is the same as that of the transformer 15A and thus will not be described in detail.

As shown in FIG. 5, the second unit 50B of the present embodiment differs from the second unit 50B of the first embodiment mainly in that the second substrate 53B is omitted. In the present embodiment, an insulation layer 59 is formed on the second element head surface 54Bs of the second element insulation layer 54B. The insulation layer 59 is formed from a material including SiO₂, SiN, or the like. The insulation layer 59 is, for example, formed on the entirety of the second element head surface 54Bs. The insulation layer 59 includes the chip head surface 50s of the transformer chip 50.

The first electrode pads 51 and the second electrode pads 52 are formed on the insulation layer 59. The first electrode pads 51 and the second electrode pads 52 are exposed from the insulation layer 59 in the z-direction. In the present embodiment, the first electrode pads 51 and the second electrode pads 52 are formed on the second element head surface 54Bs of the second element insulation layer 54B. In the present embodiment, the first electrode pads 51 and the second electrode pads 52 are formed from a material including Al.

Additionally, a shield electrode portion 58C is formed on the insulation layer 59 and electrically connected to the second shield electrode 58B. The shield electrode portion 58C is formed from a material selected from one or more of, for example, Ti, TiN, Ta, TaN, Au, Ag, Cu, Al, and W. In the present embodiment, the shield electrode portion 58C is formed from a material including Al. Thus, the shield electrode portion 58C and the second shield electrode 58B are formed from different materials. The shield electrode portion 58C is formed from the same material as the first electrode pads 51 and the second electrode pads 52.

A method for manufacturing the second unit 50B will now be described.

The method for manufacturing the second unit 50B includes a step of preparing a Si wafer, a step of forming an electrode pad, a step of forming an insulation layer, a step of forming a second element insulation layer, a step of forming a high-voltage coil, a step of forming a second connection electrode, and a step of removing the Si wafer.

In the step of preparing a Si wafer, an oxide film may be formed on the surface of the Si wafer. In the step of forming an electrode pad, the first electrode pads 51 and the second electrode pads 52 are formed on the Si wafer through, for example, sputtering. The first electrode pads 51 and the second electrode pads 52 are formed from a material including, for example, Al. In the step of forming an insulation layer, the insulation layer 59 is formed through, for example, chemical vapor deposition (CVD). The insulation layer 59 is, for example, a SiO₂ film. In the step of forming a second element insulation layer, the etching stopper films 54P and the interlayer insulation films 54Q are alternately stacked on one another. The etching stopper films 54P and the interlayer insulation films 54Q are formed through, for example, CVD. The etching stopper film 54P is, for example, a SiN film. The interlayer insulation film 54Q is, for example, a SiO₂ film.

The step of forming a high-voltage coil and the step of forming a second connection electrode are performed during the step of forming the second element insulation layer.

In the step of forming a high-voltage coil, for example, etching is performed on an etching stopper film 54P and an interlayer insulation film 54Q that are located at a position for formation of a high-voltage coil to form a coil opening. The coil opening is filled with a metal material. An example of the metal material is Cu. As a result, the high-voltage coil 22A (22B) is formed.

In the step of forming a second connection electrode, a single interlayer insulation film 54Q is formed on a single etching stopper film 54P. Then, for example, etching is performed to form a connection electrode opening in the etching stopper film 54P and the interlayer insulation film 54Q. The connection electrode opening is filled with a metal material. An example of the metal material is Cu. That is, the step of forming a second element insulation layer and the step of forming a second connection electrode are alternately performed.

Subsequent to the step of forming a second element insulation layer and the step of forming a second connection electrode, in the step of removing the Si wafer, the Si wafer is removed by, for example, grinding. As a result, the first electrode pads 51 and the second electrode pads 52 are exposed. The steps described above manufacture the second unit 50B.

### Advantages

The present embodiment obtains the following advantages in addition to the advantages (1-1) to (1-4) and (1-6) of the first embodiment.

(2-1) The second unit 50B includes the first electrode pads 51 and the second electrode pads 52 exposed from the second element head surface 54Bs of the second element insulation layer 54B.

This structure allows the insulation layer 59 to be smaller in thickness than the second substrate 53B of the first embodiment. Thus, the thickness of the second unit 50B is reduced. Accordingly, the height of the transformer chip 50 is reduced.

### Third Embodiment

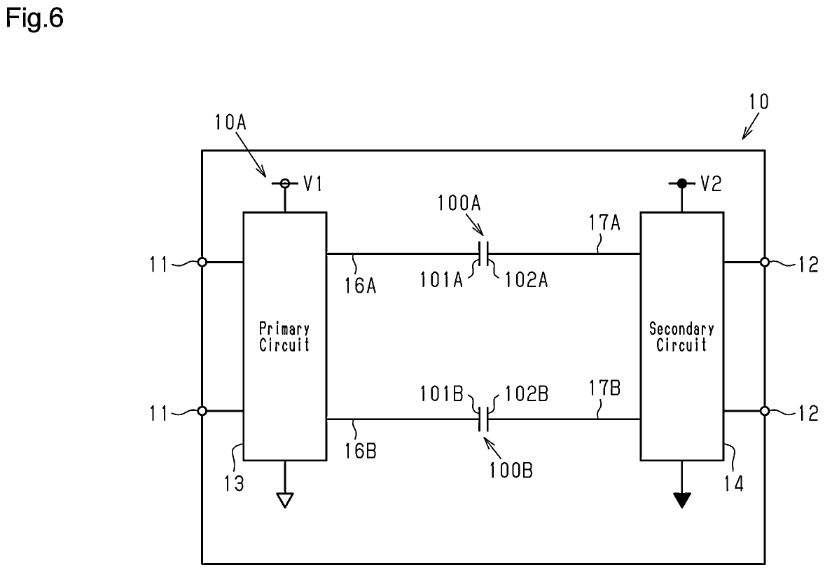

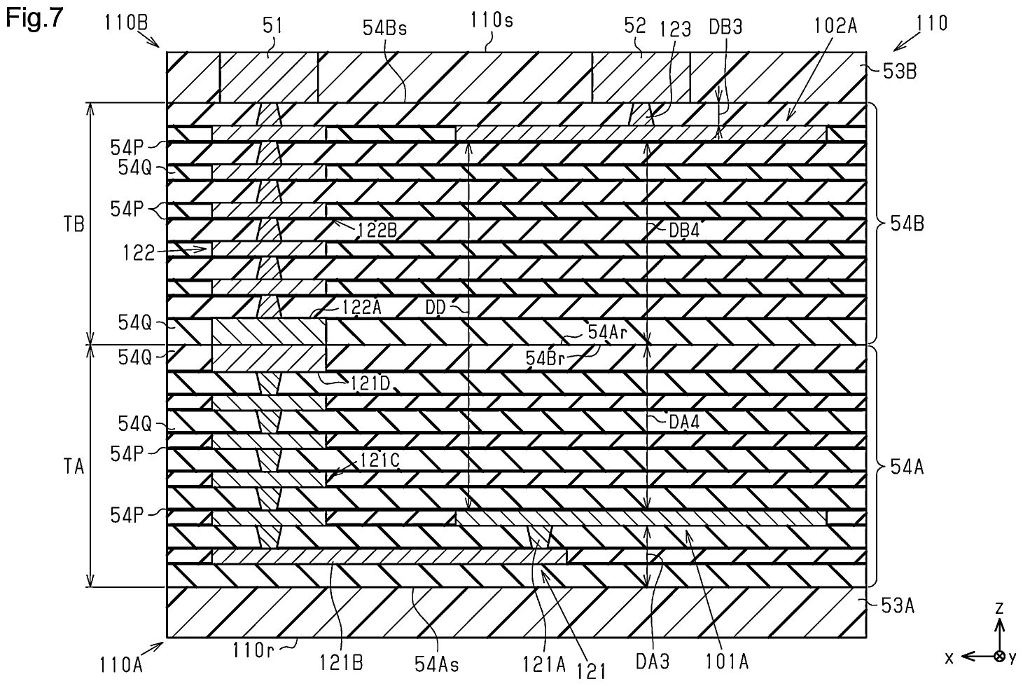

A third embodiment of the signal transmission device 10 and the transformer chip 50 will now be described with reference to FIGS. 6 and 7. The transformer chip 50 of the present embodiment differs from the transformer chip 50 of the first embodiment in that the first insulation element and the second insulation element are formed of capacitors instead of coils. In the description below, the same reference characters are given to those components that are the same as the corresponding components of the first embodiment. Such components will not be described in detail.

As shown in FIG. 6, the signal transmission device 10 includes capacitors 100A and 100B instead of the transformers 15A and 15B.

While transmitting a first signal from the primary circuit 13 to the secondary circuit 14, the capacitor 100A electrically insulates the primary circuit 13 from the secondary circuit 14. The capacitor 100A includes a first electrode 101A and a second electrode 102A. The first electrode 101A is connected to the primary signal line 16A. The second electrode 102A is connected to the secondary signal line 17A.

While transmitting a second signal from the primary circuit 13 to the secondary circuit 14, the capacitor 100B electrically insulates the primary circuit 13 from the secondary circuit 14. The capacitor 100B includes a first electrode 101B and a second electrode 102B. The first electrode 101B is connected to the primary signal line 16B. The second electrode 102B is connected to the secondary signal line 17B. In the present embodiment, the first electrodes 101A and 101B correspond to a “first insulation element.” The second electrodes 102A and 102B correspond to a “second insulation element.”

In the present embodiment, the insulation withstand voltage of the capacitors 100A and 100B is, for example, in a range of 2500 Vrms to 7500 Vrms. The insulation withstand voltage of the capacitors 100A and 100B may be in a range of 2500 Vrms to 5700 Vrms. However, the insulation withstand voltage of the capacitors 100A and 100B is not limited to these values and may be any specific numerical value.

As shown in FIG. 7, the signal transmission device 10 includes a capacitor chip 110 instead of the transformer chip 50 (refer to FIG. 2). FIG. 7 is a schematic cross-sectional view showing a cross-sectional structure of the capacitor chip 110 taken along the xz-plane. FIG. 7 shows the capacitor 100A. The structure of the capacitor 100B is the same as that of the capacitor 100A and thus will not be described in detail. In the present embodiment, the capacitor chip 110 corresponds to an “insulating chip.”

The structure of the capacitor chip 110 is obtained by changing the low-voltage coils 21A and 21B and the high-voltage coils 22A and 22B of the transformer chip 50 to the capacitors 100A and 100B. In the capacitor chip 110, the same reference characters are given to those components that are the same as the corresponding components of the transformer chip 50. Such components will not be described in detail.

The capacitor chip 110 has the form of a rectangular plate. The capacitor chip 110 includes a chip head surface 110s and a chip back surface 110r that face opposite directions in the z-direction. The chip head surface 110s faces the same direction as the chip head surface 40s of the second chip 40 (refer to FIG. 2). The chip back surface 110r faces the same direction as the chip back surface 40r of the second chip 40 (refer to FIG. 2). The chip back surface 110r faces the secondary die pad 70 (refer to FIG. 2).

The capacitor chip 110 includes a first unit 110A and a second unit 110B. The second unit 110B is disposed on the first unit 110A.

The first unit 110A includes the first substrate 53A, the first element insulation layer 54A, the first electrode 101A, and a first connection electrode 121.

The first electrode 101A is an electrode plate that is flat and has a thickness in the z-direction. As viewed in the z-direction, the first electrode 101A is rectangular. The first electrode 101A is embedded in the first element insulation layer 54A. The first electrode 101A is arranged at a position separated from the first element back surface 54Ar in the z-direction. As viewed in the z-direction, the shape of the first electrode 101A may be changed in any manner.

More specifically, the first electrode 101A is disposed closer to the first element head surface 54As than a center of the first element insulation layer 54A between the first element head surface 54As and the first element back surface 54Ar in the z-direction. That is, the first electrode 101A is disposed closer to the first element head surface 54As than the center of the first element insulation layer 54A in the thickness-wise direction (z-direction). In other words, the first electrode 101A and the second unit 110B are disposed at opposite sides of the center of the first element insulation layer 54A in the thickness-wise direction (z-direction). Therefore, a distance DA3 between the first electrode 101A and the first element head surface 54As in the z-direction is less than a distance DA4 between the first electrode 101A and the first element back surface 54Ar in the z-direction. In an example, the distance DA3 is less than or equal to ½ of the distance DA4. In an example, the distance DA3 is greater than or equal to ⅓ of the distance DA4. The distances DA3 and DA4 may each be changed in any manner.

The first connection electrode 121 is electrically connected to the first electrode 101A. The first connection electrode 121 includes a via 121A connected to the first electrode 101A, an interconnect 121B connected to the via 121A and extending in the x-direction, a connector 121C connected to the interconnect 121B and extending in the z-direction, and an electrode portion 121D connected to the connector 121C. In the present embodiment, the interconnect 121B is disposed closer to the first substrate 53A than the first electrode 101A.

The connector 121C includes vias and interconnect layers. The vias and the interconnect layers are alternately stacked on one another in the z-direction. The electrode portion 121D is exposed from the first element back surface 54Ar.

The second unit 110B includes the first electrode pads 51, the second electrode pads 52, the second substrate 53B, the second element insulation layer 54B, the second electrode 102A, a second connection electrode 122, and a via 123.

The second electrode 102A is an electrode plate that is flat and has a thickness in the z-direction. As viewed in the z-direction, the second electrode 102A is, for example, rectangular. As viewed in the z-direction, the shape of the second electrode 102A may be changed in any manner.

In the present embodiment, the second electrode 102A is equal in thickness to the first electrode 101A. When the difference in thickness between the second electrode 102A and the first electrode 101A is, for example, within 20% of the thickness of the first electrode 101A, it is considered that the second electrode 102A is equal in thickness to the first electrode 101A. The thickness of the first electrode 101A and the second electrode 102A may be changed in any manner. In an example, the second electrode 102A may be greater in thickness than the first electrode 101A.

The second electrode 102A is embedded in the second element insulation layer 54B. The second electrode 102A is arranged at a position separated from the second element back surface 54Br in the z-direction.

More specifically, the second electrode 102A is disposed closer to the second element head surface 54Bs than a center of the second element insulation layer 54B between the second element head surface 54Bs and the second element back surface 54Br in the z-direction. That is, the second electrode 102A is disposed closer to the second element head surface 54Bs than the center of the second element insulation layer 54B in the thickness-wise direction (z-direction). In other words, the second electrode 102A and the first unit 110A are disposed at opposite sides of the second element insulation layer 54B in the thickness-wise direction (z-direction). Therefore, a distance DB3 between the second electrode 102A and the second element head surface 54Bs in the z-direction is less than a distance DB4 between the second electrode 102A and the second element back surface 54Br in the z-direction. In an example, the distance DB3 is less than or equal to ½ of the distance DB4. In an example, the distance DB3 is less than or equal to ⅓ of the distance DB4. The distance DB3 is less than or equal to ⅕ of the distance DB4. The distance DB3 is less than or equal to ⅛ of the distance DB4. In an example, the distance DB3 is greater than or equal to 1/10 of the distance DB4. The distances DB3 and DB4 may each be changed in any manner. The distances DB3 and DB4 may each be changed in any manner.

In the present embodiment, the distance DB3 is less than the distance DA3. More specifically, the distance DA3 needs to be greater than the distance DB3 in correspondence with the interconnect 121B of the first connection electrode 121 being disposed below the low-voltage coil 21A. In other words, the distance DB3 may be less than the distance DA3 since the second unit 50B does not include an interconnect, such as the interconnect 121B, extending over the second electrode 102A between the second electrode 102A and the second element head surface 54Bs.

In the present embodiment, the distance DB4 between the second electrode 102A and the second element back surface 54Br of the second element insulation layer 54B in the z-direction is greater than a distance DA4 between the first electrode 101A and the first element back surface 54Ar of the first element insulation layer 54A in the z-direction. As described above, the etching stopper films 54P and the interlayer insulation films 54Q that are arranged in the second element insulation layer 54B between the second electrode 102A and the second element back surface 54Br are greater in number than the etching stopper films 54P and the interlayer insulation films 54Q that are arranged in the first element insulation layer 54A between the first electrode 101A and the first element back surface 54Ar.

The distances DA4 and DB4 may be changed in any manner. In an example, the distance DB4 may be equal to the distance DA4. When the difference between the distance DB4 and the distance DA4 is, for example, within 20% of the distance DB4, it is considered that the distance DB4 is equal to the distance DA4. In an example, the distance DB4 may be less than the distance DA4.

The second electrode 102A is electrically connected to the second electrode pad 52 by the via 123. The second electrode pad 52 overlaps the second electrode 102A as viewed in the z-direction. The via 123 connects the second electrode pad 52 and the second electrode 102A in the z-direction. The first electrode 101A and the second electrode 102A each correspond to an “electrode plate.”

The second connection electrode 122 is electrically connected to the first electrode pad 51. In the same manner as the first connection electrode 121, the second connection electrode 122 includes an electrode portion 122A and a connector 122B. The electrode portion 122A is exposed from the second element back surface 54Br. The connector 122B is connected to the first electrode pad 51. Thus, the second connection electrode 122 is disposed in the second element insulation layer 54B and exposed from the second element back surface 54Br. The connector 122B includes vias and interconnect layers. The vias and the interconnect layers are alternately stacked on one another in the z-direction.

The first unit 110A and the second unit 110B are disposed so that the first element back surface 54Ar of the first element insulation layer 54A in the first unit 110A is in contact with the second element back surface 54Br of the second element insulation layer 54B in the second unit 110B. In this state, the first connection electrode 121 is electrically connected to the second connection electrode 122.

More specifically, when the first element back surface 54Ar of the first element insulation layer 54A is in contact with the second element back surface 54Br of the second element insulation layer 54B, the electrode portion 121D of the first connection electrode 121 and the electrode portion 122A of the second connection electrode 122 face each other in the z-direction. In the present embodiment, the electrode portion 121D is in contact with the electrode portion 122A. In this state, the electrode portion 121D and the electrode portion 122A are bonded to each other by Cu—Cu bonding. The first connection electrode 121 and the second connection electrode 122 are bonded by Cu—Cu bonding. Thus, the first connection electrode 121 is electrically connected to the second connection electrode 122. The Cu—Cu bonding may be performed through a known process.

When the first unit 50A is bonded to the second unit 50B, the first electrode 101A and the second electrode 102A of the capacitor 100A are opposed to each other in the z-direction. A portion of the first element insulation layer 54A and a portion of the second element insulation layer 54B are disposed between the first electrode 101A and the second electrode 102A in the z-direction.

A distance DD between the first electrode 101A and the second electrode 102A in the z-direction is greater than each of the thickness TA of the first element insulation layer 54A and the thickness TB of the second element insulation layer 54B. The distance DD is defined by the sum of the distance DA4 and the distance DB4. In an example, the distance DD is greater than or equal to 1.5 times the thickness TA (TB). In an example, the distance DD is less than two times the thickness TA (TB).

The first electrode 101A, the second electrode 102A, the first connection electrode 121, the second connection electrode 122, and the via 123 are each formed from one or more materials selected from Ti, TiN, Ta, TaN, Au, Ag, Cu, Al, and W. In the present embodiment, the first electrode 101A, the second electrode 102A, the first connection electrode 121, the second connection electrode 122, and the via 123 are each formed from a material including Cu.

Although not shown in the drawing, the first electrode 101B (refer to FIG. 1) and a first connection electrode electrically connected to the first electrode 101B are embedded in the first element insulation layer 54A. The first electrode 101B is aligned with the first electrode 101A in the z-direction. The first electrode 101B is separated from the first electrode 101A in the y-direction.

Also, the second electrode 102B (refer to FIG. 1) and a second connection electrode electrically connected to the second electrode 102B are embedded in the second element insulation layer 54B. The second electrode 102B is aligned with the second electrode 102A in the z-direction. The second electrode 102B is separated from the second electrode 102A in the y-direction. When the first element back surface 54Ar of the first element insulation layer 54A is in contact with the second element back surface 54Br of the second element insulation layer 54B, the first electrode 101B and the second electrode 102B face each other in the z-direction. The first connection electrode electrically connected to the first electrode 101B and the second connection electrode electrically connected to the second electrode 102B are connected by Cu—Cu bonding. Thus, the first connection electrode is electrically connected to the second connection electrode. That is, the first electrode 101B is electrically connected to the first electrode pads 51. The present embodiment has the same advantages as the first embodiment.

### Fourth Embodiment

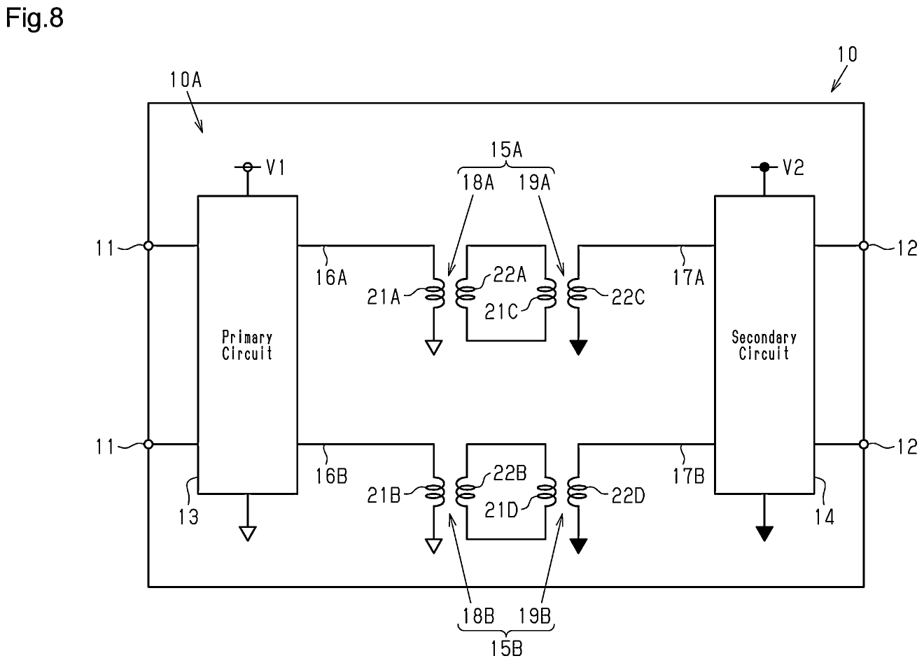

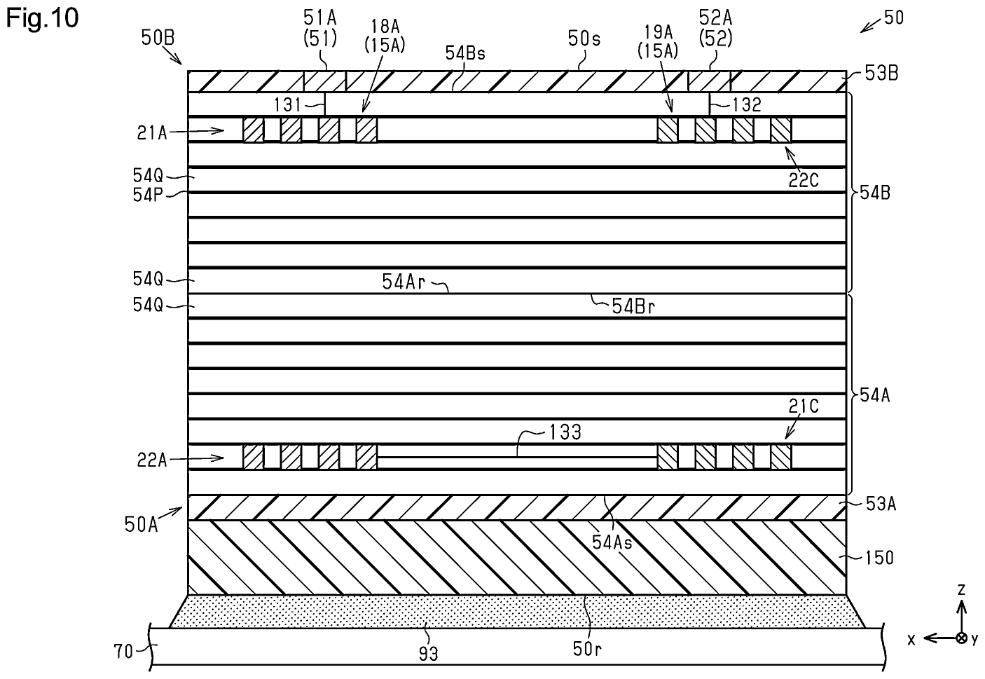

A fourth embodiment of the signal transmission device 10 and the transformer chip 50 will now be described with reference to FIGS. 8 and 10. The transformer chip 50 of the present embodiment differs from the transformer chip 50 of the first embodiment in the structure of the transformers 15A and 15B. In the description below, the same reference characters are given to those components that are the same as the corresponding components of the first embodiment. Such components will not be described in detail.

As shown in FIG. 8, the transformer 15A includes transformers 18A and 19A that are connected in series. The transformer 18A is electrically connected to the primary circuit 13. The transformer 18A includes the low-voltage coil 21A and the high-voltage coil 22A. The transformer 19A is electrically connected to the secondary circuit 14. The transformer 19A includes a first high-voltage coil 21C and a second high-voltage coil 22C insulated from the first high-voltage coil 21C and configured to be magnetically coupled to the first high-voltage coil 21C.

The low-voltage coil 21A is electrically connected by the primary signal line 16A and is also connected to the ground of the primary circuit 13. More specifically, the low-voltage coil 21A includes a first end electrically connected to the primary circuit 13 and a second end electrically connected to the ground of the primary circuit 13.

The high-voltage coil 22A is connected to the first high-voltage coil 21C of the transformer 19A. In an example, the high-voltage coil 22A and the first high-voltage coil 21C are connected to each other so as to be electrically floating. More specifically, the high-voltage coil 22A includes a first end connected to a first end of the first high-voltage coil 21C and a second end connected to a first end of the first high-voltage coil 21C. Thus, the high-voltage coil 22A and the first high-voltage coil 21C serve as relay coils that relay transmission of a signal from the low-voltage coil 21A to the second high-voltage coil 22C.

The second high-voltage coil 22C is electrically connected by the secondary signal line 17A and is also connected to the ground of the secondary circuit 14. More specifically, the second high-voltage coil 22C includes a first end electrically connected to the secondary circuit 14 and a second end electrically connected to the ground of the secondary circuit 14.

The transformer 15B includes transformers 18B and 19B that are connected in series. The transformer 18B includes the low-voltage coil 21B and the high-voltage coil 22B. The transformer 19B includes a first high-voltage coil 21D and a second high-voltage coil 22D. The transformers 18B and 19B are the same as the transformers 18A and 19A and thus will not be described in detail.

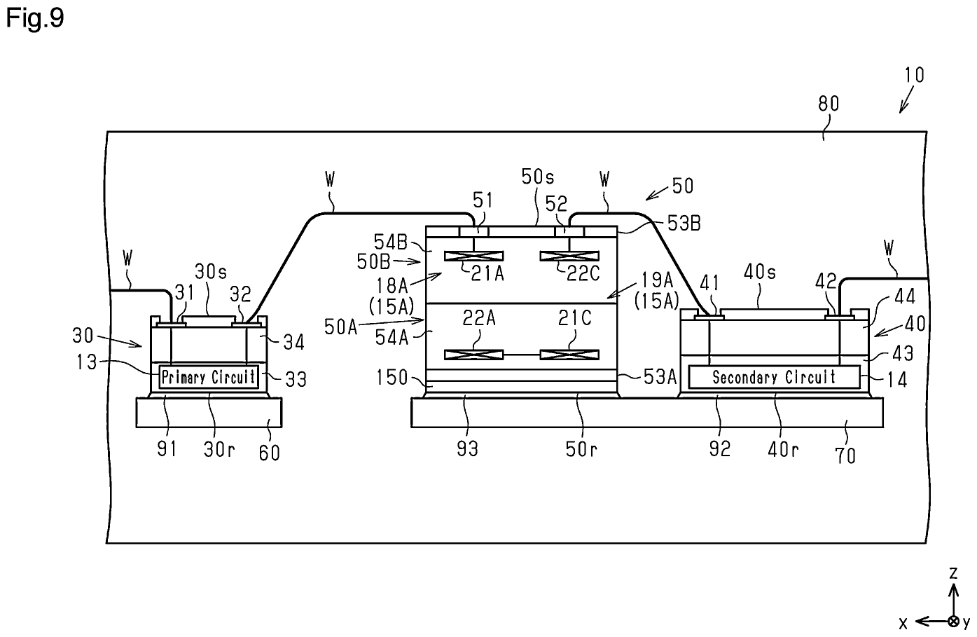

As shown in FIG. 9, the transformer chip 50 is mounted on the secondary die pad 70 with an insulation member 150 disposed between the transformer chip 50 and the secondary die pad 70. The insulation member 150 is disposed on the first substrate 53A of the first unit 50A of the transformer chip 50. The insulation member 150 includes the chip back surface 50r of the transformer chip 50. In other words, the first unit 50A includes the insulation member 150. In an example, the insulation member 150 is bonded to the first substrate 53A by an insulative bonding material. More specifically, the insulation member 150 is disposed between the third bonding material 93 and the first substrate 53A. The insulation member 150 is bonded to the secondary die pad 70 by the third bonding material 93.

FIG. 10 is a cross-sectional structure showing the low-voltage coil 21A, the high-voltage coil 22A, the first high-voltage coil 21C, and the second high-voltage coil 22C of the transformer chip 50. The configuration and arrangement of the low-voltage coil 21B, the high-voltage coil 22B, the first high-voltage coil 21D, and the second high-voltage coil 22D are the same as those of the low-voltage coil 21A, the high-voltage coil 22A, the first high-voltage coil 21C, and the second high-voltage coil 22C. In the description hereafter, the configuration and arrangement of the low-voltage coil 21A, the high-voltage coil 22A, the first high-voltage coil 21C, and the second high-voltage coil 22C will be described in detail. The configuration and arrangement of the high-voltage coil 22B, the first high-voltage coil 21D, and the second high-voltage coil 22D may not be described in detail.

As shown in FIG. 10, in the present embodiment, the first unit 50A includes the high-voltage coil 22A and the first high-voltage coil 21C. The high-voltage coil 22A is disposed closer to the first element head surface 54As than the center of the first element insulation layer 54A in the z-direction. The first high-voltage coil 21C is aligned with the high-voltage coil 22A in the z-direction. The first high-voltage coil 21C is separated from the high-voltage coil 22A in the x-direction. Although not shown in the drawing, the first unit 50A includes the high-voltage coil 22B and the first high-voltage coil 21D. The high-voltage coil 22B and the first high-voltage coil 21D are aligned with the high-voltage coil 22A in the z-direction. The high-voltage coil 22B is separated from the high-voltage coil 22A in the y-direction. The first high-voltage coil 21D is separated from the first high-voltage coil 21C in the y-direction. The high-voltage coils 22A and 22B and the first high-voltage coils 21C and 21D each correspond to a “first insulation element.” The high-voltage coils 22A and 22B each correspond to a “first conductor.” The first high-voltage coils 21C and 21D each correspond to a “second conductor.”

In the present embodiment, the second unit 50B includes the low-voltage coil 21A and the second high-voltage coil 22C. The low-voltage coil 21A is disposed closer to the second element head surface 54Bs than the center of the second element insulation layer 54B in the z-direction. The second high-voltage coil 22C is aligned with the low-voltage coil 21A in the z-direction. The second high-voltage coil 22C is separated from the low-voltage coil 21A in the x-direction. Although not shown in the drawing, the second unit 50B includes the low-voltage coil 21B and the second high-voltage coil 22D. The low-voltage coil 21B and the second high-voltage coil 22D are aligned with the low-voltage coil 21A in the z-direction. The second high-voltage coil 22D is separated from the low-voltage coil 21B in the x-direction. The low-voltage coil 21B is separated from the low-voltage coil 21A in the y-direction. The second high-voltage coil 22D is separated from the second high-voltage coil 22C in the y-direction. The low-voltage coils 21A and 21B and the second high-voltage coils 22C and 22D each correspond to a “second insulation element.” The low-voltage coils 21A and 21B each correspond to a “third conductor.” The second high-voltage coils 22C and 22D each correspond to a “fourth conductor.”

When the first unit 50A is bonded to the second unit 50B, the low-voltage coil 21A and the high-voltage coil 22A are opposed to each other in the z-direction. A portion of the first element insulation layer 54A and a portion of the second element insulation layer 54B are disposed between the low-voltage coil 21A and the high-voltage coil 22A in the z-direction. The low-voltage coil 21B and the high-voltage coil 22B are also opposed to each other in the z-direction.

The low-voltage coil 21A is electrically connected to the first electrode pad 51A by a via 131. The second high-voltage coil 22C is electrically connected to the second electrode pad 52A by a via 132.

The high-voltage coil 22A is electrically connected to the first high-voltage coil 21C in the first element insulation layer 54A. More specifically, a high-voltage interconnect 133 is disposed in the first element insulation layer 54A. The high-voltage coil 22A and the first high-voltage coil 21C are electrically connected by the high-voltage interconnect 133.

When the first unit 50A is bonded to the second unit 50B, the first high-voltage coil 21C and the second high-voltage coil 22C are opposed to each other in the z-direction. A portion of the first element insulation layer 54A and a portion of the second element insulation layer 54B are disposed between the first high-voltage coil 21C and the second high-voltage coil 22C in the z-direction. The first high-voltage coil 21D and the second high-voltage coil 22D are also opposed to each other in the z-direction.

The first high-voltage coil 21C and the second high-voltage coil 22C are formed from one or more material selected from Ti, TiN, Ta, TaN, Au, Ag, Cu, Al, and W. The material forming the first high-voltage coil 21C and the second high-voltage coil 22C may be the same as that forming the low-voltage coil 21A and the high-voltage coil 22A. In the present embodiment, the first high-voltage coil 21C and the second high-voltage coil 22C are each formed from a material including Cu. The vias 131 and 132 and the high-voltage interconnect 133 are formed from one or more materials selected from Ti, TiN, Ta, TaN, Au, Ag, Cu, Al, and W.

### Advantages

The present embodiment has the following advantages.

(4-1) The transformer chip 50 includes the transformers 18A (18B) and 19A (19B) connected in series. The transformers 18A (18B) and 19A (19B) are arranged in the x-direction, which is orthogonal to the thickness-wise direction of the first element insulation layer 54A (the thickness-wise direction of the second element insulation layer 54B).

In this structure, the transformers 18A (18B) and 19A (19B) that are connected in series are arranged in the x-direction. Thus, while limiting an increase in the distance between the first element head surface 54As and the first element back surface 54Ar of the first element insulation layer 54A in the z-direction and the distance between the second element head surface 54Bs and the second element back surface 54Br in the second element insulation layer 54B in the z-direction, the insulation withstand voltage of the transformer chip 50 is improved.

(4-2) The insulation member 150 is disposed between the secondary die pad 70 and the transformer chip 50.

This structure increases the distance from the low-voltage coil 21A (21B) and the second high-voltage coil 22C (22D) to the secondary die pad 70 in the z-direction as compared to a structure in which the insulation member 150 is not disposed between the secondary die pad 70 and the transformer chip 50. Thus, the insulation withstand voltage between the transformer chip 50 and the secondary die pad 70 is increased.

(4-3) The insulation member 150 and the secondary die pad 70 are bonded by the third bonding material 93. The third bonding material 93 is an insulative bonding material.

This structure increases the insulation distance from the low-voltage coil 21A (21B) and the second high-voltage coil 22C (22D) to the secondary die pad 70 in the z-direction as compared to a structure in which the third bonding material 93 is a conductive bonding material. Thus, the insulation withstand voltage between the transformer chip 50 and the secondary die pad 70 is increased.

### Modified Examples

The embodiments described above may be modified as follows. The embodiments described above and the modified examples described below can be combined as long as the combined modifications remain technically consistent with each other. In an example, the low-voltage coils 21A and 21B, the high-voltage coils 22A and 22B, the first high-voltage coils 21C and 21D, and the second high-voltage coils 22C and 22D in the fourth embodiment may each be changed to an electrode plate (electrode of capacitor) such as that in the third embodiment.

### Modified Example of Transformer Chip

In the third embodiment, the first unit 110A may include the first shield electrode 58A in the same manner as the first unit 50A of the first embodiment. The second unit 110B may include the second shield electrode 58B in the same manner as the second unit 50B of the first embodiment. In the first and second embodiments, the first shield electrode 58A may be omitted from the first unit 50A, and the second shield electrode 58B may be omitted from the second unit 50B.

In the third embodiment, the configurations of the first connection electrode 121 and the second connection electrode 122 may be changed in any manner.

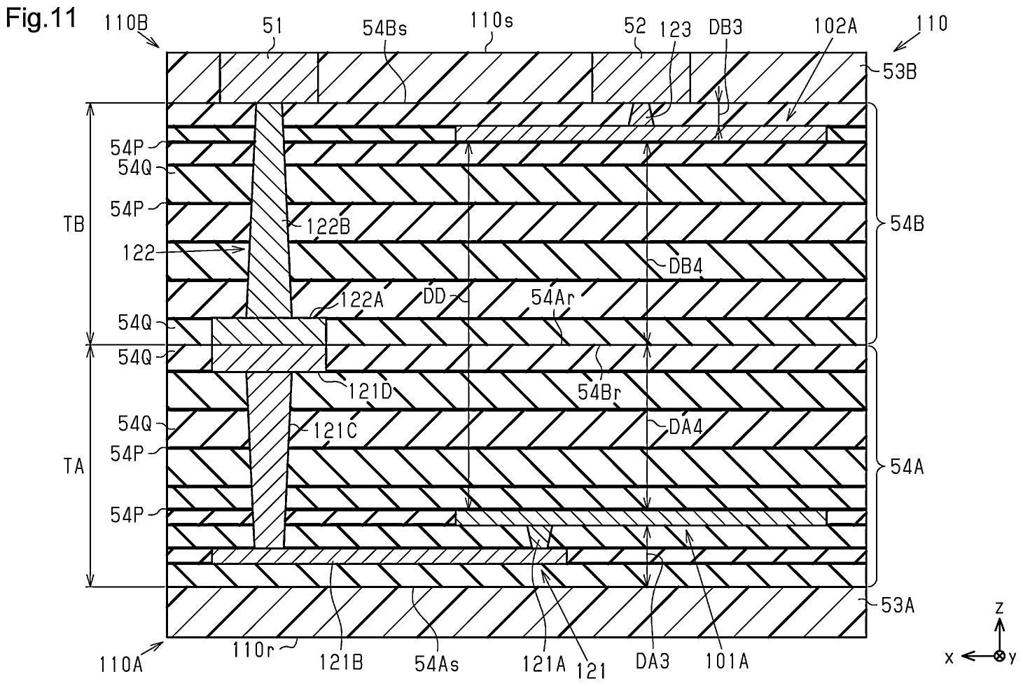

FIG. 11 shows an example of a first connection electrode 121 that differs from the first connection electrode 121 of the third embodiment in the configuration of the connector 121C. The connector 121C shown in FIG. 11 is formed of a via extending in the z-direction. In the example shown, the connector 121C is tapered from the electrode portion 121D toward the interconnect 121B.

The second connection electrode 122 differs from the second connection electrode 122 of the third embodiment in the configuration of the connector 122B. The connector 122B shown in FIG. 11 is formed of a via extending in the z-direction. In the example shown, the connector 122B is tapered from the electrode portion 122A toward the first electrode pad 51. Thus, the tapering direction of the connector 122B differs from the tapering direction of the connector 121C. The first embodiment and the second embodiment may be changed in the same manner.

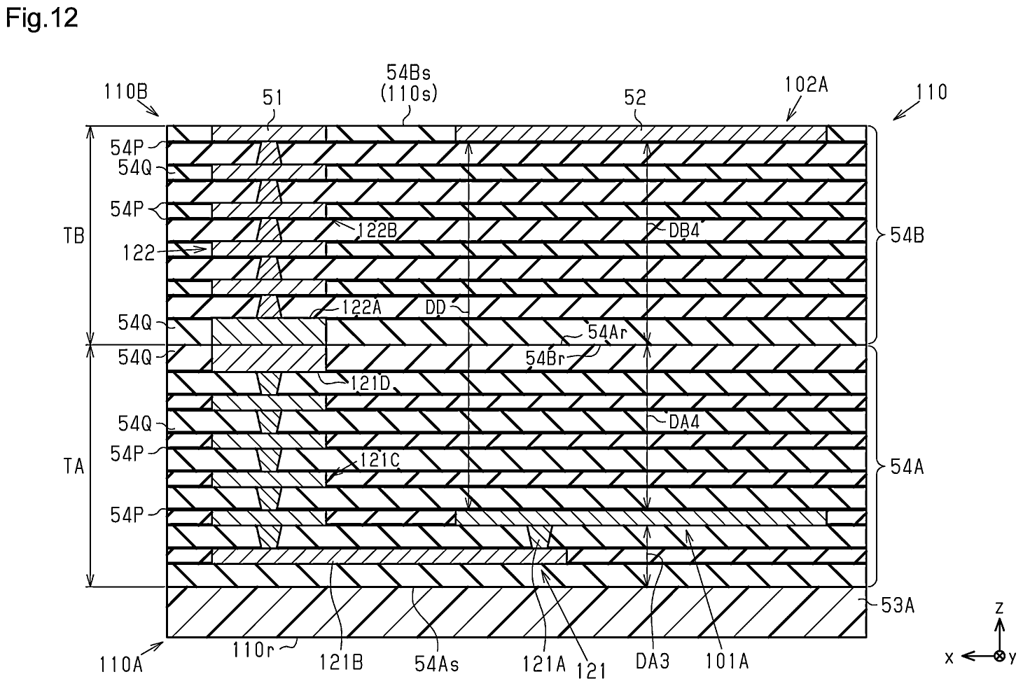

In the third embodiment, the z-direction of the second electrode 102A may be changed in any manner. In an example, as shown in FIG. 12, the second electrode 102A may be exposed from the second element head surface 54Bs of the second element insulation layer 54B. In this case, the second electrode 102A includes the second electrode pad 52.

Also, the connector 122B of the second connection electrode 122 is exposed from the second element head surface 54Bs of the second element insulation layer 54B. More specifically, the connector 122B includes an interconnect layer that is exposed from the second element head surface 54Bs. In this case, the interconnect layer exposed from the second element head surface 54Bs includes the first electrode pads 51.

In this structure, the second electrode 102A is disposed closer to the second element head surface 54Bs of the second element insulation layer 54B in correspondence with omission of the via 123. Thus, the distance DD between the first electrode 101A and the second electrode 102A is increased. This improves the insulation withstand voltage of the capacitor chip 110. In addition, omission of the via 123, the first electrode pads 51, and the second electrode pads 52 simplifies the structure of the capacitor chip 110.

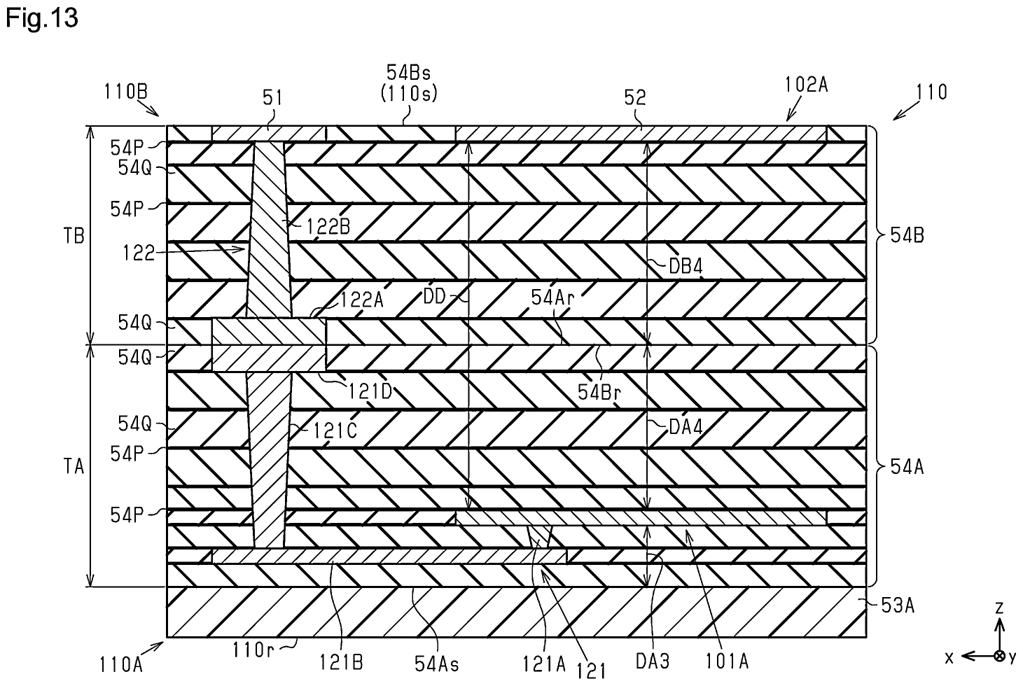

In the modified example shown in FIG. 12, the configurations of the first connection electrode 121 and the second connection electrode 122 may be changed in any manner. In an example, as shown in FIG. 13, the configurations of the connector 121C of the first connection electrode 121 and the connector 122B of the second connection electrode 122 may be changed to vias such as those shown in FIG. 11. In this case, the first electrode pad 51 is exposed from the second element head surface 54Bs. The first electrode pad 51 is connected to the connector 122B.

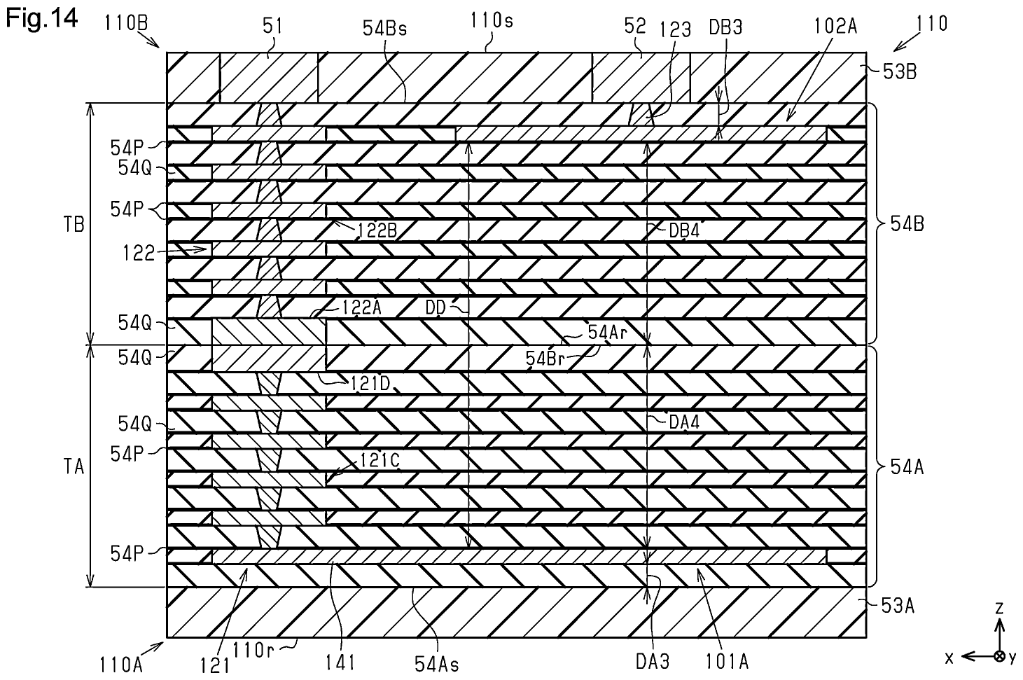

In the third embodiment, the connection configuration of the first electrode 101A and the first connection electrode 121 may be changed in any manner. In an example, as shown in FIG. 14, the first electrode 101A may include an extension 141 extending toward the connector 121C from one of two ends of the first electrode 101A in the y-direction that is located closer to the connector 121C. The extension 141 may be formed integrally with the first electrode 101A. The extension 141 extends in the y-direction from a portion of the first electrode 101A in the x-direction. The extension 141 is connected to the connector 121C. Hence, in the modified example shown in FIG. 14, the via 121A and the interconnect 121B are omitted from the first connection electrode 121.

In this structure, the first electrode 101A is disposed closer to the first element head surface 54As of the first element insulation layer 54A in correspondence with omission of the via 121A. Thus, the distance DD between the first electrode 101A and the second electrode 102A is increased. This improves the insulation withstand voltage of the capacitor chip 110. In addition, omission of the via 121A and the interconnect 121B from the first connection electrode 121 simplifies the structure of the first connection electrode 121.

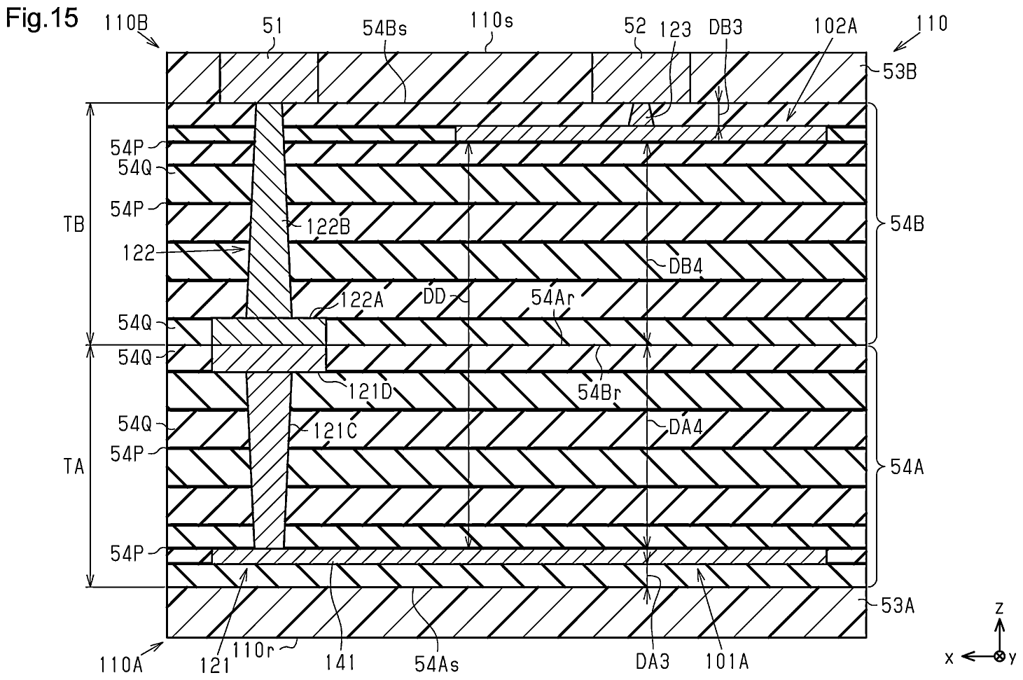

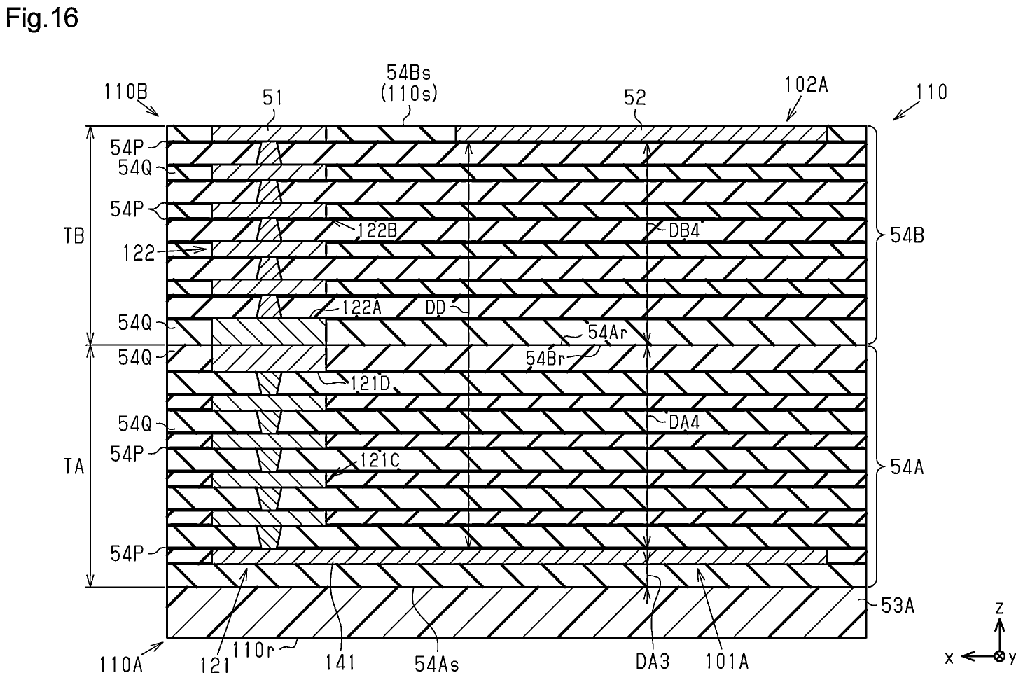

In the modified example shown in FIG. 14, the configurations of the first connection electrode 121 and the second connection electrode 122 may be changed in any manner. In an example, as shown in FIG. 15, the configurations of the connector 121C of the first connection electrode 121 and the connector 122B of the second connection electrode 122 may be changed to vias such as those shown in FIG. 11. In the modified example shown in FIG. 14, as shown in FIG. 16, the second electrode 102A may be exposed from the second element head surface 54Bs of the second element insulation layer 54B. In this case, the second electrode 102A includes the second electrode pad 52.

Also, the connector 122B of the second connection electrode 122 is exposed from the second element head surface 54Bs of the second element insulation layer 54B. More specifically, the connector 122B includes an interconnect layer that is exposed from the second element head surface 54Bs. In this case, the interconnect layers include the first electrode pads 51.

With this structure, the distance DD between the first electrode 101A and the second electrode 102A is further increased. Accordingly, the insulation withstand voltage of the capacitor chip 110 is further improved. In addition, omission of the via 123, the first electrode pads 51, and the second electrode pads 52 simplifies the structure of the capacitor chip 110.

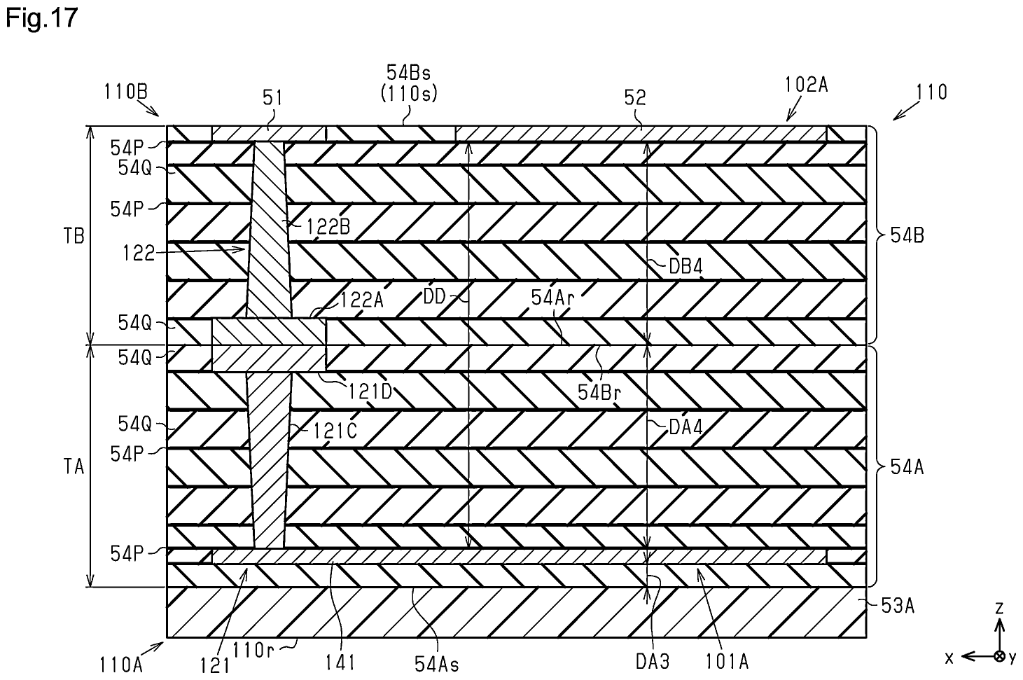

In the modified example shown in FIG. 16, the configurations of the first connection electrode 121 and the second connection electrode 122 may be changed in any manner. In an example, as shown in FIG. 17, the configurations of the connector 121C of the first connection electrode 121 and the connector 122B of the second connection electrode 122 may be changed to vias such as those shown in FIG. 11. In this case, the first electrode pad 51 is exposed from the second element head surface 54Bs. The first electrode pad 51 is connected to the connector 122B.

In the third embodiment, the configuration of the first element insulation layer 54A may be changed in accordance with the material forming the first electrode 101A or the like. The configuration of the second element insulation layer 54B may be changed in accordance with the material forming the second electrode 102A or the like. In the modified examples shown in FIGS. 11 to 17, the configurations of first element insulation layer 54A and the second element insulation layer 54B may also be changed in the same manner. A case in which the first electrode 101A, the second electrode 102A, and the like are formed from a material other than materials containing Cu will now be described. An example of such a material is Al.

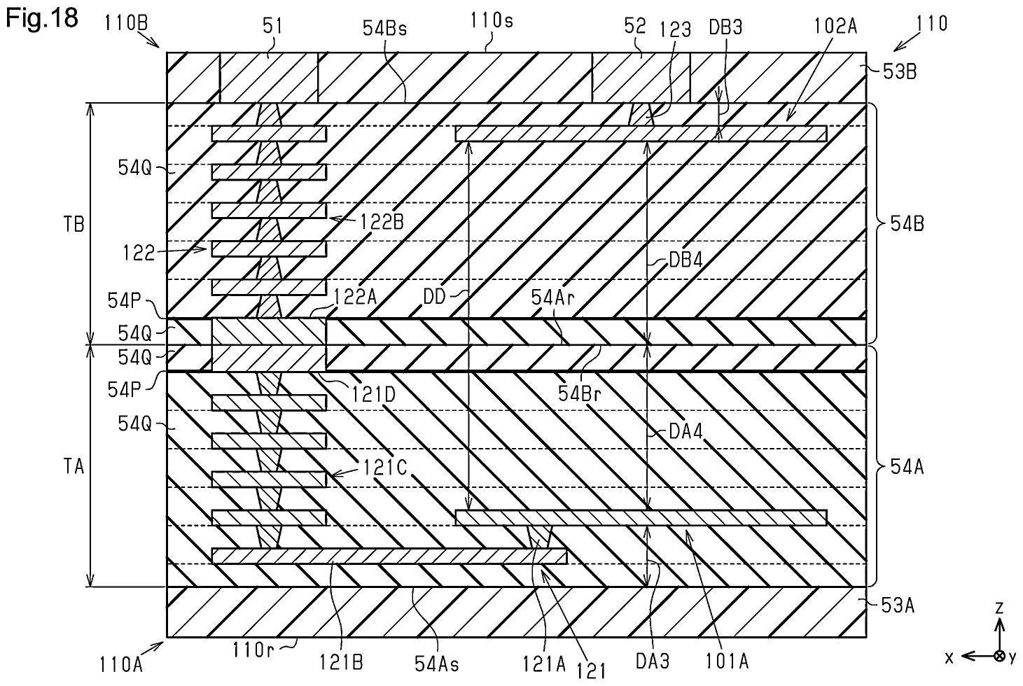

FIG. 18 is a cross-sectional structure of the capacitor chip 110 corresponding to the third embodiment shown in FIG. 7. As shown in FIG. 18, the first element insulation layer 54A includes a single etching stopper film 54P. More specifically, the first element insulation layer 54A includes a single etching stopper film 54P and multiple interlayer insulation films 54Q. The etching stopper film 54P and the first element back surface 54Ar are disposed at opposite sides of one of the interlayer insulation films 54Q that includes the first element back surface 54Ar. The etching stopper film 54P is in contact with the interlayer insulation film 54Q including the first element back surface 54Ar. The electrode portion 121D is disposed in an opening extending through both the etching stopper film 54P and the interlayer insulation film 54Q including the first element back surface 54Ar in the z-direction. The electrode portion 121D includes a surface that defines the first element back surface 54Ar and an opposite surface that is in contact with the interlayer insulation film 54Q located immediately below the etching stopper film 54P.

The second element insulation layer 54B includes a single layer of etching stopper film 54P. More specifically, the second element insulation layer 54B includes a single etching stopper film 54P and multiple interlayer insulation films 54Q. The etching stopper film 54P and the second element back surface 54Br are disposed at opposite sides of one of the interlayer insulation films 54Q that includes the second element back surface 54Br. The etching stopper film 54P is in contact with the interlayer insulation film 54Q including the second element back surface 54Br. The electrode portion 122A is disposed in an opening extending through both the etching stopper film 54P and the interlayer insulation film 54Q including the second element back surface 54Br in the z-direction. The electrode portion 122A includes a surface that defines the second element back surface 54Br and an opposite surface that is in contact with the interlayer insulation film 54Q disposed immediately on the etching stopper film 54P.

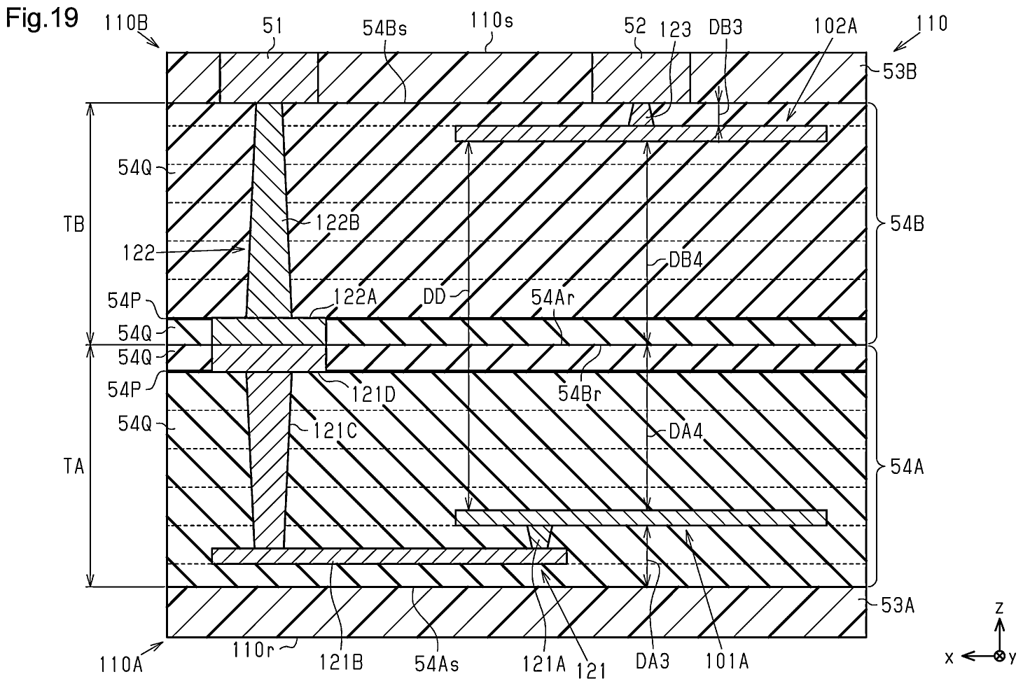

FIG. 19 is a cross-sectional structure of the capacitor chip 110 corresponding to the modified example shown in FIG. 11. As shown in FIG. 19, the first element insulation layer 54A includes a single etching stopper film 54P. The configuration of the first element insulation layer 54A is the same as that of the first element insulation layer 54A shown in FIG. 18. The second element insulation layer 54B includes a single etching stopper film 54P. The configuration of the second element insulation layer 54B is the same as that of the second element insulation layer 54B shown in FIG. 18.

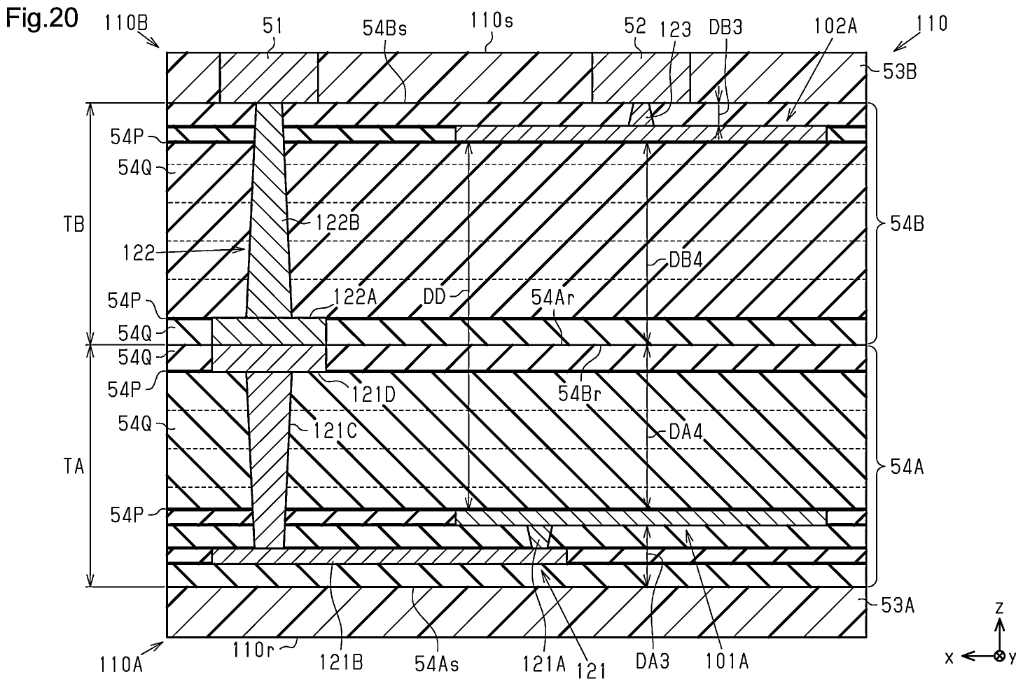

In the modified example shown in FIG. 11, the connector 121C of the first connection electrode 121 and the connector 122B of the second connection electrode 122 may be formed from a material (e.g., Al) other than Cu. In such a case, as shown in FIG. 20, the etching stopper film 54P may be omitted from the first element insulation layer 54A between the first electrode 101A and the electrode portion 121D in the z-direction. The etching stopper film 54P is disposed in contact with a surface of the electrode portion 121D that is located at the side of the first element back surface 54Ar. The etching stopper film 54P may also be omitted from a portion of the second element insulation layer 54B between the second electrode 102A and the electrode portion 122A in the z-direction. The modified examples shown in FIGS. 12 to 17 may be changed in the same manner.

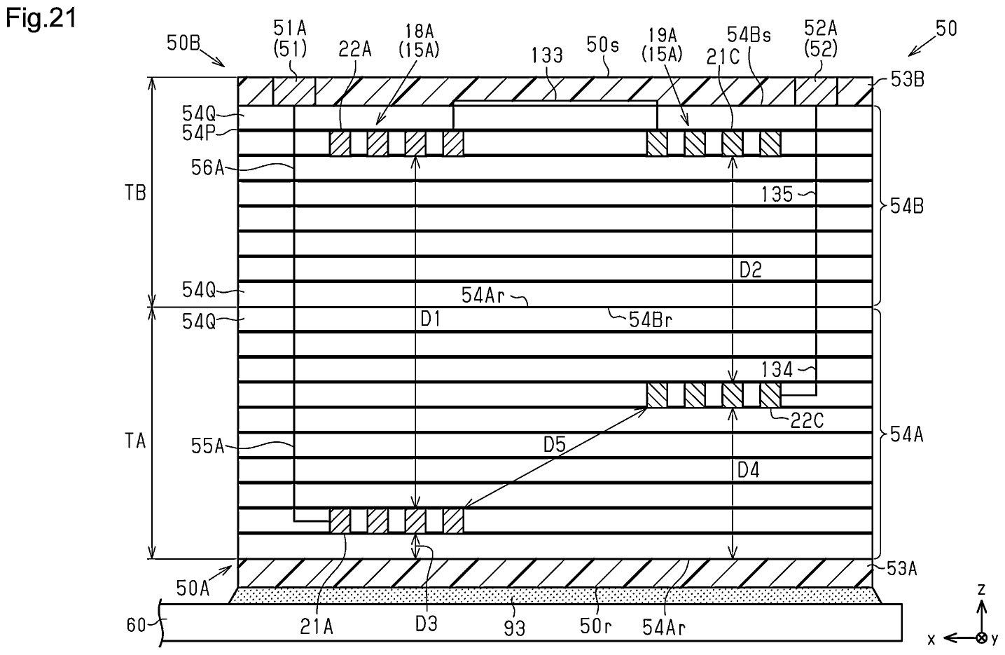

In the fourth embodiment, the insulation member 150 disposed between the transformer chip 50 and the secondary die pad 70 may be omitted. FIG. 21 shows an example in which the transformer chip 50 is mounted on the primary die pad 60. The internal structure of the transformer chip 50 will now be described. The transformer chip 50 differs from that of the third embodiment in the arrangement of the low-voltage coil 21A, the high-voltage coil 22A, the first high-voltage coil 21C, and the second high-voltage coil 22C.

More specifically, the first unit 50A includes the low-voltage coil 21A and the second high-voltage coil 22C. The second unit 50B includes the high-voltage coil 22A and the first high-voltage coil 21C. In the first element insulation layer 54A of the first unit 50A, the low-voltage coil 21A and the second high-voltage coil 22C are disposed at different positions in the z-direction. In the illustrated example, the second high-voltage coil 22C is disposed closer to the first element back surface 54Ar than the low-voltage coil 21A. In other words, the low-voltage coil 21A is disposed closer to the first element head surface 54As than the second high-voltage coil 22C. The second high-voltage coil 22C is disposed closer to the first element back surface 54Ar than the center of the first element insulation layer 54A in the z-direction. The low-voltage coil 21A is disposed closer to the first element head surface 54As than the center of the first element insulation layer 54A in the z-direction.

In the second element insulation layer 54B of the second unit 50B, the high-voltage coil 22A is aligned with the first high-voltage coil 21C in the z-direction. The high-voltage coil 22A and the first high-voltage coil 21C are both disposed closer to the second element head surface 54Bs than the center of the second element insulation layer 54B in the z-direction. Therefore, a distance D2 between the first high-voltage coil 21C and the second high-voltage coil 22C in the z-direction is less than a distance DI between the low-voltage coil 21A and the high-voltage coil 22A in the z-direction. The distance DI is greater than each of the thickness TA of the first element insulation layer 54A and the thickness TB of the second element insulation layer 54B. The distance D2 is less than each of the thickness TA of the first element insulation layer 54A and the thickness TB of the second element insulation layer 54B. As viewed in the y-direction, the second high-voltage coil 22C is disposed between the low-voltage coil 21A and the high-voltage coil 22A. A distance D4 between the second high-voltage coil 22C and the first substrate 53A in the z-direction is greater than a distance D3 between the low-voltage coil 21A and the first substrate 53A in the z-direction. That is, the second high-voltage coil 22C is disposed farther from the primary die pad 60 than the low-voltage coil 21A in the z-direction. A distance D5 between the low-voltage coil 21A and the second high-voltage coil 22C are greater than or equal to the distance D1. The distance D5 may be greater than or equal to the distance D3.

Although not shown in the drawing, the first unit 50A includes the low-voltage coil 21B and the second high-voltage coil 22D. The second unit 50B includes the high-voltage coil 22B and the first high-voltage coil 21D. The low-voltage coil 21B, the high-voltage coil 22B, the first high-voltage coil 21D, and the second high-voltage coil 22D are arranged in the same manner.

The low-voltage coils 21A and 21B and the second high-voltage coils 22C and 22D each correspond to a “first insulation element.” The low-voltage coils 21A and 21B each correspond to a “first conductor.” The second high-voltage coils 22C and 22D each correspond to a “second conductor.” The high-voltage coils 22A and 22B and the first high-voltage coils 21C and 21D each correspond to a “second insulation element.” The high-voltage coils 22A and 22B each correspond to a “third conductor.” The first high-voltage coils 21C and 21D correspond to a “fourth conductor.”

The first unit 50A includes the first connection electrode 55A connected to the low-voltage coil 21A and a first connection electrode 134 connected to the second high-voltage coil 22C. The first connection electrodes 55A and 134 are disposed on the first element insulation layer 54A. The second unit 50B includes the second connection electrode 56A connected to the first electrode pads 51, a second connection electrode 135 connected to the second electrode pads 52, and the high-voltage interconnect 133 electrically connecting the high-voltage coil 22A and the first high-voltage coil 21C. The second connection electrodes 56A and 135 are disposed on the second element insulation layer 54B.

Although simplified in FIG. 21, the configurations of the first connection electrode 55A and the second connection electrode 56A are the same as those in the first embodiment. The second connection electrode 56A is connected to the first electrode pad 51A. The first connection electrode 55A and the second connection electrode 56A are bonded by Cu—Cu bonding, for example, in the same manner as the first embodiment. Thus, the low-voltage coil 21A is electrically connected to the first electrode pad 51A.

The configuration of the first connection electrode 134 is the same as that of the first connection electrode 55A. The configuration of the second connection electrode 135 is the same as that of the second connection electrode 56A. The second connection electrode 135 is connected to the second electrode pad 52A. The first connection electrode 134 and the second connection electrode 135 are bonded by, for example, Cu—Cu bonding. Thus, the second high-voltage coil 22C is electrically connected to the second electrode pad 52A.

In this structure, when the signal transmission device 10 is driven, a relatively high voltage is applied to the second high-voltage coil 22C (22D), and a relatively low voltage is applied to the low-voltage coil 21A (21B). The distance between the second high-voltage coil 22C (22D) and the primary die pad 60 is greater than the distance between the low-voltage coil 21A (21B) and the primary die pad 60. Thus, the insulation withstand voltage of the transformer chip 50 is improved.

In addition, the distance between the low-voltage coil 21A (21B) and the second high-voltage coil 22C (22D), which receives a relatively high voltage when the signal transmission device 10 is driven, is increased. Thus, the insulation withstand voltage of the transformer chip 50 is improved.

In each embodiment, the configuration of adhering the first unit 50A (110A) to the second unit 50B (110B) is not limited to Cu—Cu bonding and may be changed in any manner. For example, any bonding process that allows for electrical connection of the first connection electrode 55A (55B) to the second connection electrode 56A (56B) may be used.

### Modified Examples of Signal Transmission Device

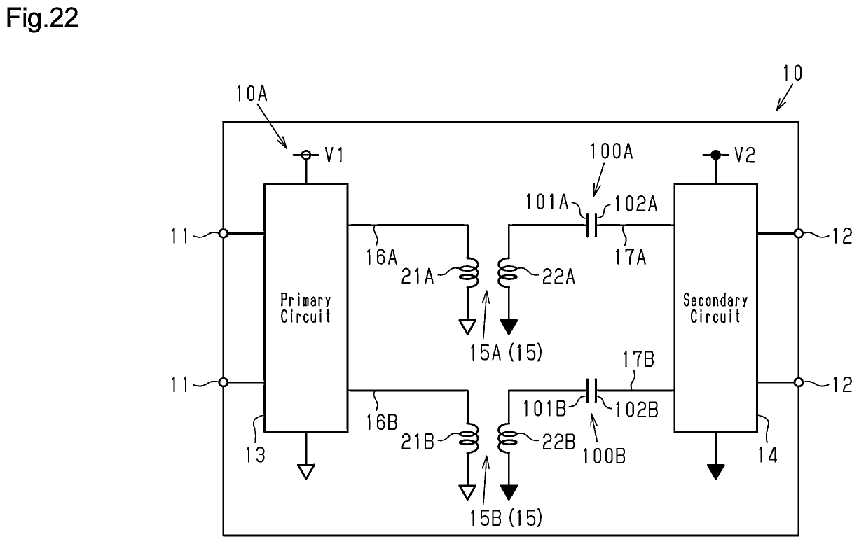

In the fourth embodiment, as shown in FIG. 22, the signal transmission device 10 may include the transformers 15A and 15B and the capacitors 100A and 100B. More specifically, the primary circuit 13 and the secondary circuit 14 may be insulated by the transformers 15A and 15B and the capacitors 100A and 100B. The transformer 15A and the capacitor 100A are connected in series. The transformer 15B and the capacitor 100B are connected in series.

More specifically, the low-voltage coil 21A of the transformer 15A is connected to the primary circuit 13 by the primary signal line 16A. The high-voltage coil 22A of the transformer 15A is electrically connected to the first electrode 101A of the capacitor 100A. The connection configuration of the first electrode 101A and the primary circuit 13 is the same as that in the first embodiment. The second electrode 102A of the capacitor 100A is connected to the secondary circuit 14 by the secondary signal line 17A. The connection configuration of the transformer 15B and the capacitor 100B is the same as that of the transformer 15A and the capacitor 100A and thus will not be described in detail.

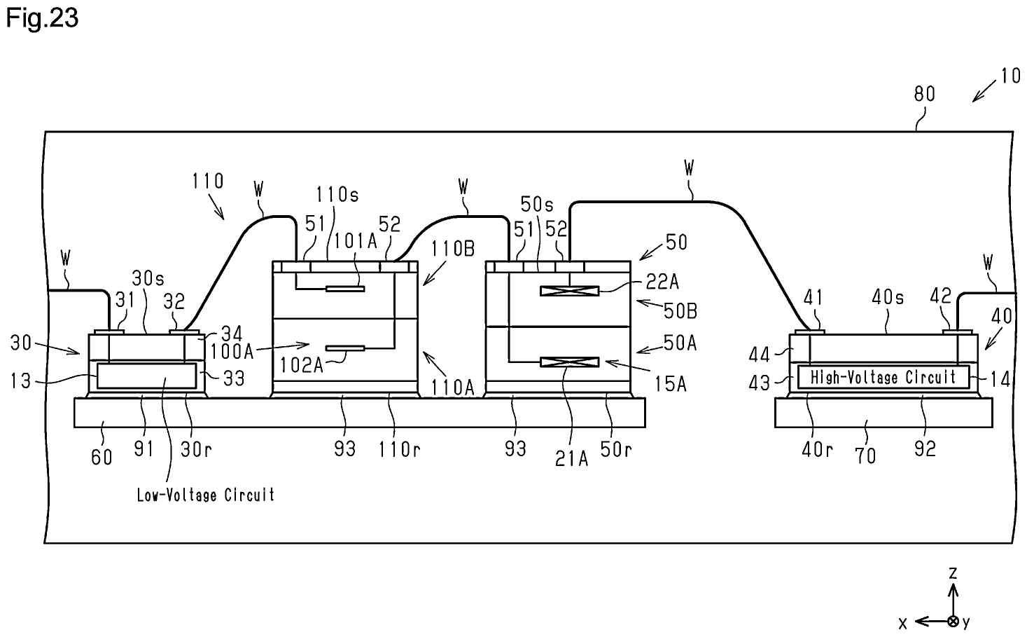

As shown in FIG. 23, the signal transmission device 10 includes the first chip 30, the second chip 40, the transformer chip 50, and the capacitor chip 110, which are semiconductor chips. The chips 30, 40, 50, and 110 are encapsulated by the encapsulation resin 80. The transformer chip 50 and the capacitor chip 110 are disposed between the first chip 30 and the second chip 40 in the x-direction. The transformer chip 50 is disposed closer to the first chip 30 than the capacitor chip 110. In other words, the capacitor chip 110 is disposed closer to the second chip 40 than the transformer chip 50. In the example shown, the first chip 30, the transformer chip 50, and the capacitor chip 110 are mounted on the primary die pad 60. The second chip 40 is mounted on the secondary die pad 70. In the modified example shown in FIG. 23, the transformer chip 50 and the capacitor chip 110 each correspond to an “insulating chip.” The transformer chip 50 corresponds to a “first insulating chip.” The capacitor chip 110 corresponds to a “second insulating chip.”

The second electrode pad 52 of the transformer chip 50 is connected to the first electrode pad 51 of the capacitor chip 110 by a wire W. Thus, the high-voltage coil 22A (22B) of the transformer 15A (15B) is electrically connecting to the first electrode 101A (101B) of the capacitor 100A (100B). The second electrode pad 52 of the capacitor chip 110 is connected to the first electrode pad 41 of the second chip 40 by a wire W. Thus, the second electrode 102A (102B) of the capacitor 100A (100B) is electrically connected to the secondary circuit 14.

The arrangement of the transformer chip 50 and the capacitor chip 110 may be changed in any manner. In an example, the transformer chip 50 is mounted on the primary die pad 60. The capacitor chip 110 may be mounted on the secondary die pad 70. In an example, the transformer chip 50 and the capacitor chip 110 may be mounted on the secondary die pad 70.

The capacitor 100A (100B) may be disposed closer to the primary circuit 13 instead of being disposed closer to the secondary circuit 14 than the transformer 15A (15B). In this case, the primary circuit 13 is electrically connected to the first electrode 101A (101B) of the capacitor 100A (100B). The second electrode 102A (102B) is electrically connected to the low-voltage coil 21A of the transformer 15A (15B). The high-voltage coil 22A is electrically connected to the secondary circuit 14. In this configuration, while the capacitor chip 110 is mounted on the primary die pad 60, the transformer chip 50 may be mounted on the secondary die pad 70.

In each embodiment, the arrangement of the transformer chip 50 may be changed in any manner. In an example, the transformer chip 50 may be mounted on the primary die pad 60. In this case, the first chip 30 and the transformer chip 50 may be mounted on the primary die pad 60.

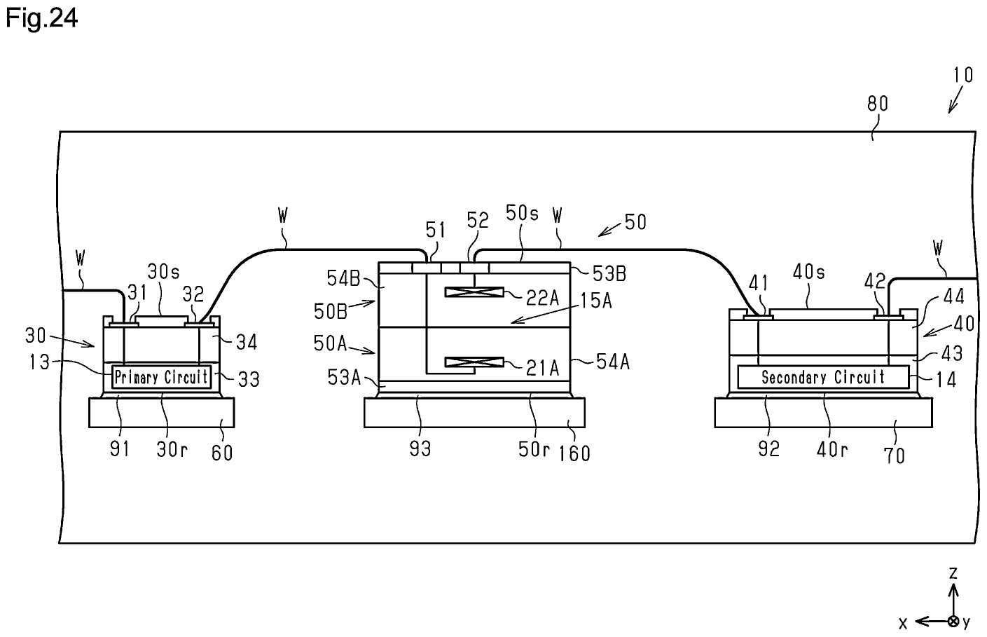

As shown in FIG. 24, the transformer chip 50 may be mounted on an intermediate die pad 160. The intermediate die pad 160 is disposed between the primary die pad 60 and the secondary die pad 70 in the x-direction. The intermediate die pad 160 is electrically disconnected from the primary die pad 60 and the secondary die pad 70. That is, the intermediate die pad 160 is electrically floating with respect to the primary die pad 60 and the secondary die pad 70. The intermediate die pad 160 corresponds to a “third die pad.”

In the fourth embodiment, the signal transmission device 10 may include two capacitors connected in series instead of the transformer 15A. The signal transmission device 10 may include two capacitors connected in series instead of the transformer 15B.

In the fourth embodiment, the transformer chip 50 may be divided into a first transformer chip and a second transformer chip. The first transformer chip includes the transformers 18A and 18B arranged in a single package. The second transformer chip includes the transformers 19A and 19B arranged in a single package. In an example, the first transformer chip is mounted on the primary die pad 60. The second transformer chip is mounted on the secondary die pad 70. The first transformer chip and the second transformer chip are disposed between the first chip 30 and the second chip 40 in the x-direction. The first transformer chip is connected to the first chip 30 by a wire W. The second transformer chip is connected to the second chip 40 by a wire W. The first transformer chip and the second transformer chip are connected by a wire W. Thus, the low-voltage coil 21A (21B) is electrically connected to the primary circuit 13. The second high-voltage coil 22C (22D) is electrically connected to the secondary circuit 14. The high-voltage coil 22A (22B) is electrically connected to the first high-voltage coil 21C (21D).

The first transformer chip and the second transformer chip may be mounted on an intermediate die pad that is electrically floating with respect to the primary die pad 60 and the secondary die pad 70. That is, the signal transmission device 10 includes the intermediate die pad. The intermediate die pad is disposed between the primary die pad 60 and the secondary die pad 70 in the x-direction.

In the fourth embodiment, the transformer chip 50 may be changed to the capacitor chip 110. The capacitor chip 110 may be divided into a first capacitor chip and a second capacitor chip. The first capacitor chip includes a capacitor 100A (100B) arranged in a single package. The second capacitor chip includes a capacitor arranged in a single package and connected in series to the capacitor 100A (100B). In an example, the first capacitor chip is mounted on the primary die pad 60. The second capacitor chip is mounted on the secondary die pad 70. The first capacitor chip and the second capacitor chip are disposed between the first chip 30 and the second chip 40 in the x-direction. The first capacitor chip is connected to the first chip 30 by a wire W. The second capacitor chip is connected to the second chip 40 by a wire W. The first capacitor chip and the second capacitor chip are connected by a wire W. Thus, the first electrode 101A (101B) is electrically connected to the primary circuit 13. The second electrode of the capacitor in the second capacitor chip is electrically connected to the secondary circuit 14. The second electrode 102A (102B) is electrically connected to the first electrode of the capacitor of the second capacitor chip. The first capacitor chip and the second capacitor chip may be mounted on the intermediate die pad.

As described above, the first transformer chip and the first capacitor chip each correspond to a “first insulating chip.” The second transformer chip and the second capacitor chip each correspond to a “second insulating chip.” The intermediate die pad corresponds to a “third die pad.”

The transformer chip 50 may be used in a device other than the signal transmission device 10 of each embodiment.

In a first example, the transformer chip 50 may be used in, for example, a primary circuit module. More specifically, the primary circuit module includes the first chip 30, the transformer chip 50, and an encapsulation resin encapsulating the chips 30 and 50. The primary circuit module further includes the primary die pad 60 on which the first chip 30 and the transformer chip 50 are mounted. The first chip 30 is bonded to the primary die pad 60 by the first bonding material 91. The transformer chip 50 is bonded to the primary die pad 60 by the third bonding material 93. In this case, the primary circuit 13 (refer to FIG. 1) included in the first chip 30 corresponds to a “signal transmission circuit.” The first chip 30 corresponds to a “circuit chip.” The primary circuit module corresponds to an “isolation module.”

In a second example, the transformer chip 50 may be used in, for example, a secondary circuit module. More specifically, the secondary circuit module includes the second chip 40, the transformer chip 50, and an encapsulation resin encapsulating the chips 40 and 50. The secondary circuit module further includes the secondary die pad 70 on which the second chip 40 and the transformer chip 50 are mounted. The second chip 40 is bonded to the secondary die pad 70 by the second bonding material 92. The transformer chip 50 is bonded to the secondary die pad 70 by the third bonding material 93. In this case, the secondary circuit 14 (refer to FIG. 1) included in the second chip 40 corresponds to a “signal transmission circuit.” The second chip 40 corresponds to a “circuit chip.” The secondary circuit module corresponds to an “isolation module.”

In a third example, only the transformer chip 50 may be modularized. More specifically, an isolation module includes the transformer chip 50 and an encapsulation resin encapsulating the transformer chip 50. The isolation module includes a die pad on which the transformer chip 50 is mounted. The transformer chip 50 is bonded to the die pad by the third bonding material 93. The first to third examples may also be applied to the capacitor chip 110.

In each embodiment, the configuration of the signal transmission device 10 may be changed in any manner.

In an example, the signal transmission device 10 may include the second chip 40 and the primary circuit module described above. In this case, the second chip 40 may be mounted on the secondary die pad 70, and the secondary die pad 70 and the second chip 40 may be encapsulated by an encapsulation resin to form a module. The signal transmission device 10 includes the above-described module and the primary circuit module.

In an example, the signal transmission device 10 may include the secondary circuit module and the first chip 30. In this case, the first chip 30 may be mounted on the primary die pad 60, and the primary die pad 60 and the first chip 30 may be encapsulated by an encapsulation resin to form a module. The signal transmission device 10 includes the above-described module and the secondary circuit module.

In an example, in the third embodiment, the primary circuit 13 or the secondary circuit 14 may be disposed in the capacitor chip 110. In this case, the interconnect layer of the connector 121C of the first connection electrode 121 and the interconnect layer of the connector 122B of the second connection electrode 122 may be electrically connected to the primary circuit 13 or the secondary circuit 14. When the primary circuit 13 is disposed in the capacitor chip 110, the signal transmission device 10 includes the capacitor chip 110 and the second chip 40, which are semiconductor chips. In other words, the signal transmission device 10 does not include the first chip 30. The capacitor chip 110 is mounted on the primary die pad 60. The second chip 40 is mounted on the secondary die pad 70. When the secondary circuit 14 is disposed in the capacitor chip 110, the signal transmission device 10 includes the first chip 30 and the capacitor chip 110, which are semiconductor chips. In other words, the signal transmission device 10 does not include the second chip 40. The first chip 30 is mounted on the primary die pad 60. The capacitor chip 110 is mounted on the secondary die pad 70.

In each embodiment, the direction of a signal transmitted in the signal transmission device 10 may be changed in any manner. In an example, the signal transmission device 10 may be configured to transmit a signal from the secondary circuit 14 to the primary circuit 13 through the transformer 15. More specifically, when a drive circuit is electrically connected to the secondary circuit 14 through the secondary terminals 12 and the secondary terminals 12 receive a signal (e.g., feedback signal) from the drive circuit, the secondary circuit 14 transmits a signal to the primary circuit 13 through the transformer 15. Then, the signal is output from the primary circuit 13 to the controller, which is electrically connected to the primary circuit 13 through the primary terminals 11. In another example, the signal transmission device 10 may be configured to bidirectionally transmit a signal between the primary circuit 13 and the secondary circuit 14. More specifically, the signal transmission device 10 may include the primary circuit 13 and the secondary circuit 14 that is configured to perform at least one of transmission of a signal and reception of a signal with the primary circuit 13 through the transformer 15.

In the present disclosure, the term “on” includes the meaning of “above” in addition to the meaning of “on” unless otherwise clearly indicated in the context. Thus, the phrase “A is formed on B” is intended to mean that A may be disposed directly on B in contact with B in the embodiments and also that A may be disposed above B without contacting B in modified examples. In other words, the term “on” does not exclude a structure in which another member is formed between A and B.

The z-direction as referred to in the present disclosure does not necessarily have to be the vertical direction and does not necessarily have to be fully aligned with the vertical direction. In the structures according to the present disclosure, “upward” and “downward” in the z-direction as referred to in the present description are not limited to “upward” and “downward” in the vertical direction. In an example, the x-direction may be aligned with the vertical direction. In another example, the y-direction may be aligned with the vertical direction.

### CLAUSES

The technical aspects that are understood from the embodiments and the modified examples will be described below. To facilitate understanding without intention to limit, the reference signs of the elements in the embodiments are given to the corresponding elements in the clause with parentheses. The reference signs are used as examples to facilitate understanding, and the components in each reference sign are not limited to those components given with the reference signs.

Clause 1

An insulating chip (50), including:

a first unit (50A); and

a second unit (50B) disposed on the first unit (50A), in which

the first unit (50A) includes

a first element insulation layer (54A) including a first element back surface (54Ar) facing the second unit (50B) and a first element head surface (54As) opposite to the first element back surface (54Ar),

a first insulation element (21A) embedded in the first element insulation layer (54A) at a position separated from the first element back surface (54Ar) in a thickness-wise direction (z-direction) of the first element insulation layer (54A), and

a first connection electrode (55A) disposed in the first element insulation layer (54A) and exposed from the first element back surface (54Ar), the first connection electrode (55A) being electrically connected to the first insulation element (21A),

the second unit (50B) includes

a second element insulation layer (54B) including a second element back surface (54Br) opposed to the first element back surface (54Ar) and a second element head surface (54Bs) opposite to the second element back surface (54Br),

a second insulation element (22A) embedded in the second element insulation layer (54B) at a position separated from the second element back surface (54Br) in a thickness-wise direction (z-direction) of the second element insulation layer (54B) and opposed to the first insulation element (21A), and

a second connection electrode (56A) disposed in the second element insulation layer (54B) and exposed from the second element back surface (54Br),

the first unit (50A) and the second unit (50B) are disposed so that the first element back surface (54Ar) is in contact with the second element back surface (54Br) and the first connection electrode (55A) is electrically connected to the second connection electrode (56A).

Clause 2

The insulating chip according to clause 1, in which

the first insulation element (21A) is disposed closer to the first element head surface (54As) than a center of the first element insulation layer (54A) in the thickness-wise direction (z-direction), and

the second insulation element (22A) is disposed closer to the second element head surface (54Bs) than a center of the second element insulation layer (54B) in the thickness-wise direction (z-direction).

Clause 3

The insulating chip according to clause 1 or 2, in which

a distance (DC) between the first insulation element (21A) and the second insulation element (22A) is greater than a thickness (TA) of the first element insulation layer (54A) and a thickness (TB) of the second element insulation layer (54B).

Clause 4

The insulating chip according to any one of clauses 1 to 3, in which

the first element insulation layer (54A) and the second element insulation layer (54B) each include

a first insulation film (54P), and

a second insulation film (54Q) formed on the first insulation film (54P), in which

the first element back surface (54Ar) and the second element back surface (54Br) are each formed of the second insulation film (54Q).

Clause 5

The insulating chip according to any one of clauses 1 to 4, in which

the first connection electrode (55A) and the second connection electrode (56A) are each formed of a material including Cu, and

the first connection electrode (55A) and the second connection electrode (56A) are bonded by Cu—Cu bonding.

Clause 6

The insulating chip according to any one of clauses 1 to 5, in which the first unit (50A) includes a first substrate (53A) disposed on the first element head surface (54As).

Clause 7

The insulating chip according to any one of clauses 1 to 6, in which the second unit (50B) includes an external electrode (51, 52) exposed from the second element head surface (54Bs).

Clause 8

The insulating chip according to any one of clauses 1 to 6, in which

the second unit (50B) includes a second substrate (53B) disposed on the second element head surface (54Bs), and

the second substrate (53B) includes an external electrode (51, 52).

Clause 9

The insulating chip according to any one of clauses 1 to 8 in which the first insulation element and the second insulation element are each a coil (21A, 22A).

Clause 10

The insulating chip according to any one of clauses 1 to 8 in which the first insulation element and the second insulation element are each an electrode plate (101A, 102A).

Clause 11

The insulating chip according to any one of clauses 1 to 8 in which

the first insulation element and the second insulation element are each an electrode plate (101A, 102A), and

the second insulation element (102A) includes an external electrode exposed from the second element head surface (54Bs).

Clause 12

The insulating chip according to clause 10 or 11, in which

the first connection electrode (121) includes an electrode portion (121D) exposed from the first element back surface (54Ar) and a connector (121C) extending in the thickness-wise direction (z-direction) of the first element insulation layer (54A) and being connected to the electrode portion (121D),

the first insulation element (21A) includes an extension (141) overlapping the connector (121C) as viewed in the thickness-wise direction (z-direction) of the first element insulation layer (54A), and

the extension (141) is in contact with the connector (121C).

Clause 13

The insulating chip according to any one of clauses 1 to 12, in which

the first insulation element includes

a first conductor (22A, 102A) disposed in the first element insulation layer (54A) closer to the first element head surface (54As) than to the first element back surface (54Ar), and

a second conductor (21C, 101C) disposed in the first element insulation layer (54A) closer to the first element head surface (54As) than to the first element back surface (54Ar) and separated from the first conductor (22A, 102A) in a first direction (x-direction) that is orthogonal to the thickness-wise direction (z-direction) of the first element insulation layer (54A),

the second insulation element includes

a third conductor (21A, 101A) disposed in the second element insulation layer (54B) closer to the second element head surface (54Bs) than to the second element back surface (54Br),

a fourth conductor (22C, 102C) disposed in the second element insulation layer (54B) closer to the second element head surface (54Bs) than to the second element back surface (54Br) and separated from the third conductor (21A, 101A) in the first direction (x-direction), and

the first conductor (22A, 102A) is electrically connected to the second conductor (21C, 101C).

Clause 14

A signal transmission device (10), including:

a first chip (30) including a first circuit (13);

an insulating chip (50); and

a second chip (40) including a second circuit (14) configured to perform at least one of reception of a signal and transmission of a signal with the first circuit (13) through the insulating chip (50), in which

the insulating chip (50) includes
a first unit (50A), and
a second unit (50B) disposed on the first unit (50A),

the first unit (50A) includes
a first element insulation layer (54A) including a first element back surface (54Ar) facing the second unit (50B) and a first element head surface (54As) opposite to the first element back surface (54Ar),
a first insulation element (21A) embedded in the first element insulation layer (54A) at a position separated from the first element back surface (54Ar) in a thickness-wise direction (z-direction) of the first element insulation layer (54A), and
a first connection electrode (55A) disposed in the first element insulation layer (54A) and exposed from the first element back surface (54Ar), the first connection electrode (55A) being electrically connected to the first insulation element (21A),

the second unit (50B) includes
a second element insulation layer (54B) including a second element back surface (54Br) opposed to the first element back surface (54Ar) and a second element head surface (54Bs) opposite to the second element back surface (54Br),
a second insulation element (22A) embedded in the second element insulation layer (54B) at a position separated from the second element back surface (54Br) in a thickness-wise direction (z-direction) of the second element insulation layer (54B) and opposed to the first insulation element (21A), and
a second connection electrode (56A) disposed in the second element insulation layer (54B) and exposed from the second element back surface (54Br), and

the first unit (50A) and the second unit (50B) are disposed so that the first element back surface (54Ar) is in contact with the second element back surface (54Br) and the first connection electrode (55A) is electrically connected to the second connection electrode (56A).

Clause 15

The signal transmission device according to clause 14, further including:

a first die pad (60) on which the first chip (30) is mounted; and

a second die pad (70) on which the second chip (40) is mounted,

in which the insulating chip (50) is mounted on the first die pad (60) or the second die pad (70).

Clause 16

The signal transmission device according to clause 14, further including:

a first die pad (60) on which the first chip (30) is mounted;

a second die pad (70) on which the second chip (40) is mounted; and

a third die pad (160) on which the insulating chip (50) is mounted,

in which the third die pad (160) is electrically floating with respect to the first die pad (60) and the second die pad (70).

Clause 17

The signal transmission device according to any one of clauses 14 to 16, in which

the first insulation element (22A, 21C) includes
a first conductor (22A) disposed in the first element insulation layer (54A) closer to the first element head surface (54As) than to the first element back surface (54Ar), and
a second conductor (21C) disposed in the first element insulation layer (54A) closer to the first element head surface (54As) than to the first element back surface (54Ar) and separated from the first conductor (22A) in a first direction (x-direction) that is orthogonal to the thickness-wise direction (z-direction) of the first element insulation layer (54A),

the second insulation element (21A, 22C) includes
a third conductor (21A) disposed in the second element insulation layer (54B) closer to the second element head surface (54Bs) than to the second element back surface (54Br), and
a fourth conductor (22C) disposed in the second element insulation layer (54B) closer to the second element head surface (54Bs) than to the second element back surface (54Br) and separated from the third conductor (21A) in the first direction (x-direction),

the first conductor (22A) is electrically connected to the second conductor (21C),

the first unit (50A) and the second unit (50B) are disposed so that the first element back surface (54Ar) is in contact with the second element back surface (54Br), and

the first circuit (13) and the second circuit (14) are connected by the first conductor (22A), the second conductor (21C), the third conductor (21A), and the fourth conductor (22C) that are connected to each other in series to transmit a signal through the first conductor (22A), the second conductor (21C), the third conductor (21A), and the fourth conductor (22C).

Clause 18

The signal transmission device according to any one of clauses 14 to 16, in which the insulating chip (50) includes a first insulating chip and a second insulating chip, the signal transmission device further including:

a first die pad (60) on which the first chip (30) and the first insulating chip are mounted; and

a second die pad (70) on which the second chip (40) and the second insulating chip are mounted.

Clause 19

The signal transmission device according to clause 14, in which the insulating chip (50) includes a first insulating chip and a second insulating chip, and the first insulating chip and the second insulating chip each include the first unit (50A) and the second unit (50B), the signal transmission device further including:

a first die pad (60) on which the first chip (30) is mounted;

a second die pad (70) on which the second chip (40) is mounted; and

a third die pad (160) on which the first insulating chip and the second insulating chip are mounted,

in which the third die pad is electrically floating with respect to the first die pad (60) and the second die pad (70).

Clause 20

The signal transmission device according to any one of clauses 14 to 16, in which

the signal transmission device (10) is configured to transmit a signal from the first circuit (13) toward the second circuit (14) through a transformer (15A, 15B) including a first coil (21A, 21B) as the first insulation element and a second coil (22A, 22B) as the second insulation element,

the transformer (15A, 15B) includes a first signal transformer (15A) and a second signal transformer (15B),

the signal transmitted through the transformer (15A, 15B) includes a first signal and a second signal,

the first signal is transmitted from the first circuit (13) toward the second circuit (14) through the first signal transformer (15A), and

the second signal is transmitted from the first circuit (13) toward the second circuit (14) through the second signal transformer (15B).

Clause 21

The insulating chip according to any one of clauses 1 to 13, in which

the first unit (50A) includes a first substrate (53A),

the first element insulation layer (54A) is formed on the first substrate (53A), and

an insulation member (150) is disposed at a side of the first substrate (53A) opposite to the first element insulation layer (54A).

Clause 22

An isolation module, including:

the insulating chip (50) according to any one of clauses 1 to 13; and

a circuit chip (30/40) including a signal transmission circuit (13/14) electrically connected to the insulating chip (50).

Clause 23

An isolation module, including:

the insulating chip (50) according to any one of clauses 1 to 13; and

an encapsulation resin that encapsulates the insulating chip.

Clause 24

An insulating chip (50), including:

a first unit (50A); and

a second unit (50B) disposed on the first unit (50A), in which

the first unit (50A) includes
a first element insulation layer (54A) including a first element back surface (54Ar) facing the second unit (50B) and a first element head surface (54As) opposite to the first element back surface (54Ar), and
a first insulation element (22A, 21C) embedded in the first element insulation layer (54A) at a position separated from the first element back surface (54Ar) in a thickness-wise direction (z-direction) of the first element insulation layer (54A),

the second unit (50B) includes
a second element insulation layer (54B) including a second element back surface (54Br) opposed to the first element back surface (54Ar) and a second element head surface (54Bs) opposite to the second element back surface (54Br),
a second insulation element (21A, 22C) embedded in the second element insulation layer (54B) at a position separated from the second element back surface (54Br) in a thickness-wise direction (z-direction) of the second element insulation layer (54B) and opposed to the first insulation element (21A), and
a second connection electrode (131, 132) disposed in the second element insulation layer (54B) and exposed from the second element back surface (54Br), the second connection electrode (131, 132) being electrically connected to the second insulation element (21A, 22C),

the first insulation element (22A, 21C) includes
a first conductor (22A) disposed in the first element insulation layer (54A) closer to the first element head surface (54As) than to the first element back surface (54Ar), and
a second conductor (21C) disposed in the first element insulation layer (54A) closer to the first element head surface (54As) than to the first element back surface (54Ar) and separated from the first conductor (22A) in a first direction (x-direction) that is orthogonal to the thickness-wise direction (z-direction) of the first element insulation layer (54A),

the second insulation element (21A, 22C) includes
a third conductor (21A) disposed in the second element insulation layer (54B) closer to the second element head surface (54Bs) than to the second element back surface (54Br), and
a fourth conductor (22C) disposed in the second element insulation layer (54B) closer to the second element head surface (54Bs) than to the second element back surface (54Br) and separated from the third conductor (21A) in the first direction (x-direction),

the first conductor (22A) is electrically connected to the second conductor (21C), and

the first unit (50A) and the second unit (50B) are disposed so that the first element back surface (54Ar) is in contact with the second element back surface (54Br).

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims and the clauses.

### REFERENCE SIGNS LIST

10) signal transmission device
10A) signal transmission circuit
11) primary terminal
12) secondary terminal
13) primary circuit
14) secondary circuit
15, 15A, 15B, 18A, 18B, 19A, 19B) transformer
16A, 16B) primary signal line
17A, 17B) secondary signal line
21A, 21B) low-voltage coil
21AA) first end
21AB) second end
21C, 21D) first high-voltage coil
22A, 22B) high-voltage coil
22AA) first end
22AB) second end
22C, 22D) second high-voltage coil
30) first chip
30s) chip head surface
30r) chip back surface
31) first electrode pad
32) second electrode pad
33) first substrate
34) wiring layer
40) second chip
40s) chip head substrate
40r) chip back surface
41) first electrode pad
42) second electrode pad
43) second substrate
44) wiring layer
50) transformer chip
50s) chip head substrate
50r) chip back surface
50A) first unit
50B) second unit
51, 51A, 51B) first electrode pad
52, 52A, 52B) second electrode pad
53A) first substrate
53B) second substrate
54A) first element insulation layer
54As) first element head surface
54Ar) first element back surface
54B) second element insulation layer
54Bs) second element head surface
54Br) second element back surface
54P) etching stopper film
54Q) interlayer insulation film
55A, 55B) first connection electrode
55AA, 55BA) first via
55AB, 55BB) interconnect
55AC, 55BC) second via
55AD, 55BD) electrode portion
56A, 56B) second connection electrode
56AA, 56BA) electrode portion
56AB, 56BB) via
57A, 57B) via
58A) first shield electrode
58B) second shield electrode
58C) shield electrode portion
59) insulation layer
60) primary die pad
70) secondary die pad
80) encapsulation resin
91) first bonding material
92) second bonding material
93) third bonding material
100A, 100B) capacitor
101A, 101B) first electrode
102A, 102B) second electrode
110) capacitor chip
110s) chip head surface
110r) chip back surface
110A) first unit
110B) second unit
121) first connection electrode
121A) via
121B) interconnect
121C) connector
121D) electrode portion
122) second connection electrode
122A) electrode portion
122B) connector
123) via
131, 132) via
133) high-voltage interconnect
134) first connection electrode
135) second connection electrode
141) extension
150) insulation member
160) intermediate die pad
W) wire
TA) total thickness of first element insulation layer
TB) total thickness of second element insulation layer
DA1) distance between low-voltage coil and first element head surface
DA2) distance between low-voltage coil and first element back surface
DA3) distance between first electrode and first element head surface
DA4) distance between first electrode and first element back surface
DB1) distance between high-voltage coil and second element head surface
DB2) distance between high-voltage coil and second element back surface
DB3) distance between second electrode and second element head surface
DB4) distance between second electrode and second element back surface
DC) distance between low-voltage coil and high-voltage coil
DD) distance between first electrode and second electrode
D1) distance between low-voltage coil and high-voltage coil
D2) distance between first high-voltage coil and second high-voltage coil
D3) distance between low-voltage coil and substrate
D4) distance between second high-voltage coil and substrate
D5) distance between low-voltage coil and second high-voltage coil

1. An insulating chip, comprising:
a first unit; and
a second unit disposed on the first unit, wherein
the first unit includes
a first element insulation layer including a first element back surface facing the second unit and a first element head surface opposite to the first element back surface,
a first insulation element embedded in the first element insulation layer at a position separated from the first element back surface in a thickness-wise direction of the first element insulation layer, and
a first connection electrode disposed in the first element insulation layer and exposed from the first element back surface, the first connection electrode being electrically connected to the first insulation element,
the second unit includes
a second element insulation layer including a second element back surface opposed to the first element back surface and a second element head surface opposite to the second element back surface,
a second insulation element embedded in the second element insulation layer at a position separated from the second element back surface in a thickness-wise direction of the second element insulation layer and opposed to the first insulation element, and
a second connection electrode disposed in the second element insulation layer and exposed from the second element back surface,
the first unit and the second unit are disposed so that the first element back surface is in contact with the second element back surface and the first connection electrode is electrically connected to the second connection electrode.

2. The insulating chip according to claim 1, wherein
the first insulation element is disposed closer to the first element head surface than a center of the first element insulation layer in the thickness-wise direction, and
the second insulation element is disposed closer to the second element head surface than a center of the second element insulation layer in the thickness-wise direction.

3. The insulating chip according to claim 1, wherein
a distance between the first insulation element and the second insulation element is greater than a thickness of the first element insulation layer and a thickness of the second element insulation layer.

4. The insulating chip according to claim 1, wherein
the first element insulation layer and the second element insulation layer each include
a first insulation film, and
a second insulation film formed on the first insulation film, wherein
the first element back surface and the second element back surface are each formed of the second insulation film.

5. The insulating chip according to claim 1, wherein
the first connection electrode and the second connection electrode are each formed of a material including Cu, and
the first connection electrode and the second connection electrode are bonded by Cu—Cu bonding.

6. The insulating chip according to claim 1, wherein the first unit includes a first substrate disposed on the first element head surface.

7. The insulating chip according to claim 1, wherein the second unit includes an external electrode exposed from the second element head surface.

8. The insulating chip according to claim 1, wherein
the second unit includes a second substrate disposed on the second element head surface, and
the second substrate includes an external electrode.

9. The insulating chip according to claim 1 wherein the first insulation element and the second insulation element are each a coil.

10. The insulating chip according to claim 1 wherein the first insulation element and the second insulation element are each an electrode plate.

11. The insulating chip according to claim 1 wherein
the first insulation element and the second insulation element are each an electrode plate, and
the second insulation element includes an external electrode exposed from the second element head surface.

12. The insulating chip according to claim 10, wherein
the first connection electrode includes an electrode portion exposed from the first element back surface and a connector extending in the thickness-wise direction of the first element insulation layer and being connected to the electrode portion,
the first insulation element includes an extension overlapping the connector as viewed in the thickness-wise direction of the first element insulation layer, and
the extension is in contact with the connector.

13. The insulating chip according to claim 1, wherein
the first insulation element includes
a first conductor disposed in the first element insulation layer closer to the first element head surface than to the first element back surface, and
a second conductor disposed in the first element insulation layer closer to the first element head surface than to the first element back surface and separated from the first conductor in a first direction that is orthogonal to the thickness-wise direction of the first element insulation layer,
the second insulation element includes
a third conductor disposed in the second element insulation layer closer to the second element head surface than to the second element back surface,
a fourth conductor disposed in the second element insulation layer closer to the second element head surface than to the second element back surface and separated from the third conductor in the first direction, and
the first conductor is electrically connected to the second conductor.

14. A signal transmission device, comprising:
a first chip including a first circuit;
an insulating chip; and
a second chip including a second circuit configured to perform at least one of reception of a signal and transmission of a signal with the first circuit through the insulating chip, wherein
the insulating chip includes
a first unit, and
a second unit disposed on the first unit, the first unit includes
a first element insulation layer including a first element back surface facing the second unit and a first element head surface opposite to the first element back surface,
a first insulation element embedded in the first element insulation layer at a position separated from the first element back surface in a thickness-wise direction of the first element insulation layer, and
a first connection electrode disposed in the first element insulation layer and exposed from the first element back surface, the first connection electrode being electrically connected to the first insulation element, the second unit includes
a second element insulation layer including a second element back surface opposed to the first element back surface and a second element head surface opposite to the second element back surface,
a second insulation element embedded in the second element insulation layer at a position separated from the second element back surface in a thickness-wise direction of the second element insulation layer and opposed to the first insulation element, and
a second connection electrode disposed in the second element insulation layer and exposed from the second element back surface, and
the first unit and the second unit are disposed so that the first element back surface is in contact with the second element back surface and the first connection electrode is electrically connected to the second connection electrode.

15. The signal transmission device according to claim 14, further comprising:
a first die pad on which the first chip is mounted; and
a second die pad on which the second chip is mounted,
wherein the insulating chip is mounted on the first die pad or the second die pad.

16. The signal transmission device according to claim 14, further comprising:
a first die pad on which the first chip is mounted;
a second die pad on which the second chip is mounted; and
a third die pad on which the insulating chip is mounted,
wherein the third die pad is electrically floating with respect to the first die pad and the second die pad.

17. The insulating chip according to claim 11, wherein
the first connection electrode includes an electrode portion exposed from the first element back surface and a connector extending in the thickness-wise direction of the first element insulation layer and being connected to the electrode portion,
the first insulation element includes an extension overlapping the connector as viewed in the thickness-wise direction of the first element insulation layer, and the extension is in contact with the connector.
